(19) United States
(12) Patent Application Publication
(10) Pub. No.: US 2025/0268010 A1
(43) Pub. Date: Aug. 21, 2025

(54) APPARATUSES INCORPORATING MICRO-LEDS AND METHODS FOR FABRICATING THE SAME

(71) Applicant: Saphlux, Inc., San Diego, CA (US)

(72) Inventors: Jie Song, San Diego, CA (US); Chen Chen, San Diego, CA (US)

(73) Assignee: Saphlux, Inc., San Diego, CA (US)

(21) Appl. No.: 18/907,447

(22) Filed: Oct. 4, 2024

Related U.S. Application Data
(63) Continuation-in-part of application No. 18/583,848, filed on Feb. 21, 2024.

(51) Int. Cl. H10H 29/851; H10H 29/34; H10H 29/80

(52) U.S. Cl. CPC H10H 29/8512; H10H 29/34; H10H 29/8323

(57) ABSTRACT

In accordance with one or more aspects of the present disclosure, an apparatus incorporating micro-LEDs is provided. The apparatus may include a first plurality of light-emitting devices for emitting light of a first color, a second light-emitting device for emitting light of a second color, and a light-conversion structure that converts light emitted by at least one of the first plurality of light-emitting devices into light of a third color. The first plurality of light-emitting devices may be fabricated on a substrate. The second light-emitting device is fabricated on a conductive via that is fabricated on the substrate. The light-conversion structure may include a plurality of quantum dots.

### CROSS-REFERENCE TO RELATED APPLICATIONS

The present application is a continuation-in-part of U.S. patent application Ser. No. 18/583,848, entitled “APPARATUSES INCORPORATING MICRO-LEDS AND METHODS FOR FABRICATING THE SAME,” filed Feb. 21, 2024, which is incorporated herein by reference in its entirety.

### TECHNICAL FIELD

The implementations of the disclosure relate generally to light-emitting devices (LEDs) and, more specifically, to apparatus incorporating micro-LEDs and methods of fabricating the same.

### BACKGROUND

Displays may employ light-emitting diodes to implement red, blue, and green pixels for producing a broad spectrum of colors for high-quality visual output. It might be desirable to integrate micro-LEDs into displays for greater pixel density and improved color accuracy. However, current techniques for display manufacturing encounter significant challenges in creating full-color displays with micro-LEDs, which primarily involve the complexities in manufacturing and precisely integrating these LEDs at a scale that is necessary for complete full-color pixel arrays.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, an apparatus is provided. The apparatus may include: a first plurality of light-emitting devices for emitting light of a first color; a second light-emitting device for emitting light of a second color; and a light-conversion structure that converts light emitted by at least one of the first plurality of light-emitting devices into light of a third color.

In some embodiments, the apparatus may further include an electrode layer fabricated on the first plurality of light-emitting devices and the second light-emitting device.

In some embodiments, the electrode layer includes a transparent electrode material.

In some embodiments, the transparent electrode material includes indium tin oxide.

In some embodiments, the electrode layer provides ohmic contact for the first plurality of light-emitting devices and the second light-emitting device.

In some embodiments, the electrode layer directly contacts a portion of a top surface of the second light-emitting device.

In some embodiments, sidewalls of the second light-emitting device are covered by a dielectric material.

In some embodiments, the electrode layer directly contacts at least a portion of a top surface of each of the first plurality of light-emitting devices.

In some embodiments, the apparatus may further include a dielectric layer fabricated on the electrode layer, wherein the light-conversion structure is fabricated in the dielectric layer.

In some embodiments, the light-conversion structure includes a plurality of quantum dots.

In some embodiments, the apparatus may further include a plurality of micro-lenses fabricated on the dielectric layer and the light-conversion structure.

In some embodiments, the apparatus may further include a substrate, wherein the first plurality of light-emitting devices is bonded to a first plurality of conductive pads of the substrate, wherein the second light-emitting device is electrically connected to a second conductive pad of the substrate through a conductive via.

In some embodiments, the first plurality of light-emitting devices is bonded to the substrate through a first plurality of conductive bonding layers.

In some embodiments, the conductive via is fabricated on the second conductive pad of the substrate.

In some embodiments, the conductive via is bonded to the second conductive pad of the substrate.

In some embodiments, the first plurality of light-emitting devices is further bonded to the substrate through a first dielectric bonding layer.

In some embodiments, the second light-emitting device is bonded to the conductive via through a second conductive bonding layer.

In some embodiments, the second light-emitting device is further bonded to the conductive via through a second dielectric bonding layer.

In some embodiments, the first color includes blue light, wherein the second color includes green light, and wherein the third color includes red light.

In some embodiments, each of the first plurality of light-emitting devices and the second light-emitting device is a micro light-emitting device.

In some embodiments, methods for fabricating an apparatus incorporating micro-LEDs are provided. The methods may include: fabricating, on a substrate, a first plurality of light-emitting devices for emitting light of a first color; fabricating, on a conductive via, a second light-emitting device for emitting light of a second color, wherein the conductive via is fabricated on the substrate; fabricating an electrode layer on the first plurality of light-emitting devices and the second light-emitting device; and fabricating, on the electrode layer, a light-conversion structure configured to convert light emitted by at least one of the first plurality of light-emitting devices into light of a third color.

In some embodiments, the electrode layer includes indium tin oxide.

In some embodiments, fabricating, on the substrate, the first plurality of light-emitting devices for emitting light of the first color includes: bonding a first light-emitting stack to the substrate; and patterning and etching the first light-emitting stack.

In some embodiments, the first light-emitting stack is bonded to the substrate through a bonding layer, wherein the bonding layer includes at least one conductive material.

In some embodiments, the first light-emitting stack is bonded to the substrate through a bonding layer and a plurality of bonding pads, wherein the bonding layer includes an insulating material, and wherein each of the plurality of bonding pads includes at least one conductive material.

In some embodiments, the methods may further include fabricating the conductive via, which includes: fabricating a first dielectric layer on the substrate; creating a first via in the first dielectric layer; and depositing a conductive material in the first via.

In some embodiments, fabricating the light-conversion structure includes fabricating a second dielectric layer on the electrode layer; creating a second via in the second dielectric layer; and placing a plurality of quantum dots in the second via.

In some embodiments, the methods may further include fabricating a plurality of micro-lenses fabricated on the second dielectric layer and the light-conversion structure.

In some embodiments, fabricating, on the conductive via, the second light-emitting device for emitting light of the second color includes: bonding a second light-emitting stack to the conductive via; and patterning and etching the second light-emitting stack.

In some embodiments, the electrode layer directly contacts at least a portion of a top surface of the second light-emitting device for emitting light of the second color.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIGS. 1A and 1B illustrate cross-sectional views of example apparatuses in accordance with some embodiments of the present disclosure.

FIG. 2 is a diagram illustrating a cross-sectional view of an example semiconductor device in accordance with some embodiments of the present disclosure.

FIGS. 3A, 3B, 3C, 3D, 3E, 3F, 3G, 3H, 3I, 3J, 3K, 3L, 3M, 3N, 3O, and 3P are schematic diagrams illustrating cross-sectional views of structures related to a process for fabricating an apparatus incorporating micro-LEDs in accordance with some embodiments of the present disclosure.

FIG. 4 is a schematic diagram illustrating an example of a light-conversion structure in accordance with some embodiments of the present disclosure.

FIG. 5 is a flow diagram illustrating an example of a process for fabricating an apparatus incorporating micro-LEDs in accordance with some embodiments of the present disclosure.

FIG. 6 depicts a schematic diagram illustrating an example pixel arrangement of an example display device in accordance with some embodiments of the present disclosure.

FIG. 7 is a diagram illustrating a cross-sectional view of an example apparatus incorporating micro light-emitting devices in accordance with some embodiments of the present disclosure.

FIGS. 8A-8P are diagrams showing cross-sectional views of device stacks for fabricating an apparatus as described in FIG. 7 in accordance with some embodiments of the present disclosure.

FIG. 9 is a diagram illustrating a cross-sectional view of an example apparatus incorporating micro light-emitting devices in accordance with some embodiments of the present disclosure.

FIGS. 10A-10S are diagrams showing cross-sectional views of structures for fabricating an apparatus as described in FIG. 7 in accordance with some embodiments of the present disclosure.

FIG. 11 is a flowchart of an example method for fabricating an apparatus containing light-emitting devices in accordance with some embodiments of the present disclosure.

### DETAILED DESCRIPTION

Aspects of the disclosure provide for apparatuses incorporating micro light-emitting devices (LEDs) and methods of fabricating the same.

In some embodiments, a display may include red pixels, green pixels, and blue pixels arranged in one or more arrays. Each of the red pixels, green pixels, and blue pixels may include one or more micro-LEDs with dimensions on the scale of micrometers. In some embodiments, a blue pixel may include a micro-LED configured to emit blue light. A green pixel may include a micro-LED configured to emit green light. In some implementations, a red pixel may include a micro-LED configured to emit blue light and a light-conversion structure configured to convert blue light into red light. In some embodiments, a red pixel may include a micro-LED configured to emit red light.

As referred to herein, a micro-LED may have dimensions on the scale of micrometers. In one implementation, a dimension (e.g., a lateral dimension) of a micro-LED may be approximately 5-25 μm. In another implementation, a dimension (e.g., a lateral dimension) of the micro-LED may be greater than 25 μm or smaller than 5 μm. A pixel pitch between two neighboring micro-LEDs may be 20 μm, 25 μm, or any other suitable value. In some embodiments, the pixel pitch may be equal to or greater than 20 μm. The pixel pitch may represent a distance between the micro-LEDs (e.g., a distance between a center of a first micro-LED and a center of a second micro-LED, a distance between a side of the first micro-LED and a side of the second micro-LED, etc.).

Examples of embodiments of the present disclosure will be described in more detail with reference to the accompanying drawings. It should be understood that the following embodiments are given by way of illustration only to provide a thorough understanding of the disclosure to those skilled in the art. Therefore, the present disclosure is not limited to the following embodiments and may be embodied in different ways. Further, it should be noted that the drawings are not to precise scale and some of the dimensions, such as width, length, thickness, and the like, can be exaggerated for clarity of description in the drawings. Like components are denoted by like reference numerals throughout the specification.

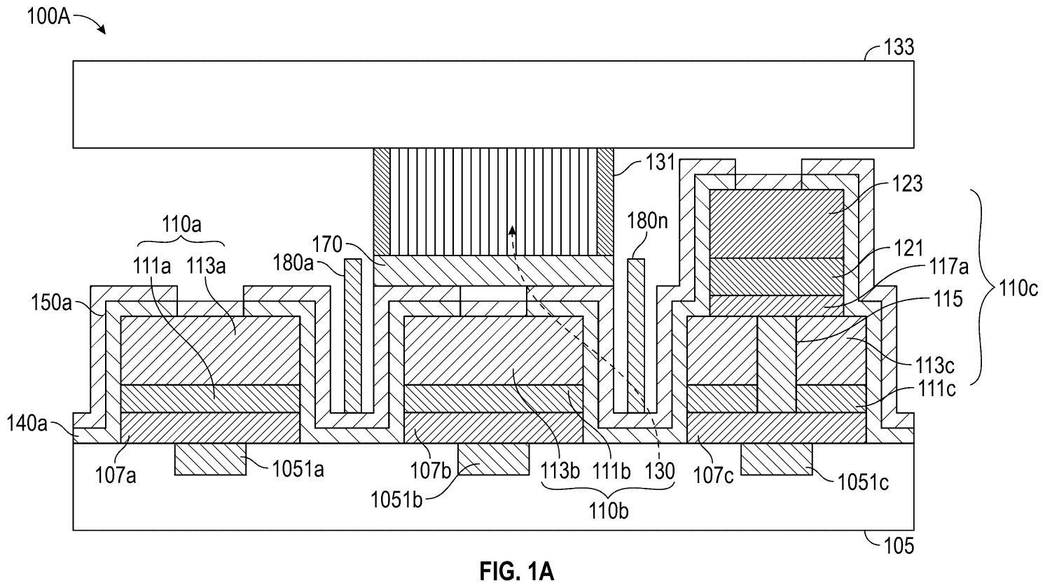

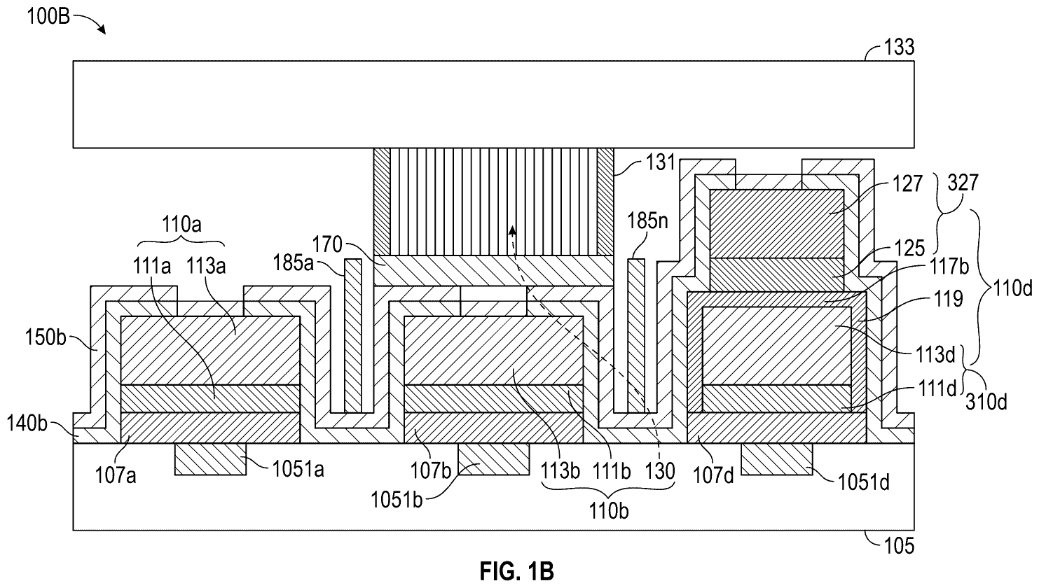

FIGS. 1A and 1B are diagrams illustrating cross-sectional views of example apparatuses 100A and 100B in accordance with some embodiments of the present disclosure. Apparatus 100A-100B may be part of a computing device (e.g., a watch, eyeglasses, contact lenses, a mobile phone, a head-mounted display, a tablet computing device, a laptop, a desktop computer, a television, an augmented reality (AR) device, a virtual reality (VR) device, etc.) and/or a display.

As shown in FIG. 1A, apparatus 100A may include pixels 110a, 110b, . . . , 110c fabricated on a substrate 105. Substrate 105 may include any suitable component for enabling individual electronic control of the light-emitting devices and/or pixels to be fabricated on substrate 105. Substrate 105 may include a silicon wafer in some embodiments. Substrate 105 may include one or more driver circuits (e.g., thin-film-transistor (TFT) driver circuits, metal-oxide-semiconductor (CMOS) driver circuits, etc.) that may control the brightness of each LED fabricated on substrate 105.

In some embodiments, substrate 105 may be a CMOS wafer including CMOS circuitry, such as one or more CMOS drivers, transistors, interconnects, etc. The pixels may be individually controlled by utilizing the driving circuitry, transistors, interconnects, etc., of the CMOS wafer. An individual pixel may be activated to emit light in response to a voltage applied via an interconnect of the CMOS substrate to the pixel and to an electrode layer 150a. A transistor or other suitable switch may provide access control to one or more pixels fabricated on substrate 105.

As shown in FIG. 1A, conductive pads 1051a, 1051b, . . . , 1051c may be fabricated on substrate 105. Each of conductive pads 1051a, 1051b, . . . , 1051c may include any suitable conductive materials, such as metals, metal nitrides, etc. In some embodiments in which substrate 105 is a CMOS substrate, conductive pads 1051a, 1051b, . . . , 1051c may be interconnects of the CMOS substrate (e.g., metallic pads, metallic vias, etc., separated by dielectric materials).

Pixels 110a, 110b, and 110c may be configured to emit light of different colors. For example, pixels 110a, 110b, and 110c may be configured to emit light of a first color (e.g., blue light), light of a second color (e.g., green light or red light), and light of a third color (e.g., red light or green light), respectively. A pixel pitch between two neighboring pixels may be 20 μm, 25 μm, or any other suitable value. In some embodiments, the pixel pitch may be equal to or greater than 20 μm. The pixel pitch may represent a distance between the micro-LEDs (e.g., a distance between a center of a first pixel and a center of a second pixel, a distance between a side of the first pixel and a side of the second pixel, etc.). While a certain number of pixels are shown in FIG. 1A, this is merely illustrative. Any suitable number of pixels may be formed on substrate 105 as described herein to fabricate a display of a suitable size.

Pixels 110a, 110b, and 110c may be bonded to substrate 105 via bonding layers 107a, 107b, and 107c, respectively. Each bonding layer 107a, 107b, and 107c may include any suitable conductive material that may bond pixels 110a, 110b, and 110c to substrate 105 and provide ohmic contact for the bottom side (e.g., the p-GaN side) of light-emitting structures 111a, 111b, and 111c, such as an Au—Sn alloy, indium, etc. As shown in FIG. 1A, bonding layers 107a, 107b, and 107c may be fabricated on conductive pads 1051a, 1051a, and 1051c, respectively. Each of bonding layers 107a, 107b, and 107c may directly contact one of conductive pads 1051a, 1051a, and 1051c or establish electrical connections with one of conductive pads 1051a, 1051b, and 1051c via other conductive materials (not shown in FIG. 1A).

Pixel 110a may include a light-emitting structure 111a and a semiconductor layer 113a. Pixel 110b may include a light-emitting structure 111b and a semiconductor layer 113b. Pixel 110c may include a light-emitting structure 111c, a semiconductor layer 113c, a conductive via 115, a bonding layer 117a, a light-emitting structure 121, and a semiconductor layer 123. As shown, conductive via 115 is fabricated in light-emitting structure 111c and semiconductor layer 113c. Conductive via 115 may directly contact bonding layer 107c or establish an electrical connection to bonding layer 107c through other electrically conductive materials. Light-emitting structure 121 and semiconductor layer 123 may be bonded to conductive via 115 and semiconductor layer 113c via bonding layer 117a. Bonding layer 117a may include any suitable conductive material that may bond light-emitting structure 121 to semiconductor layer 113c and provide ohmic contact for the bottom side (e.g., the p-GaN side) of light-emitting structure 121, such as metals, alloys (e.g., an Au—Sn alloy), conductive adhesives, etc.

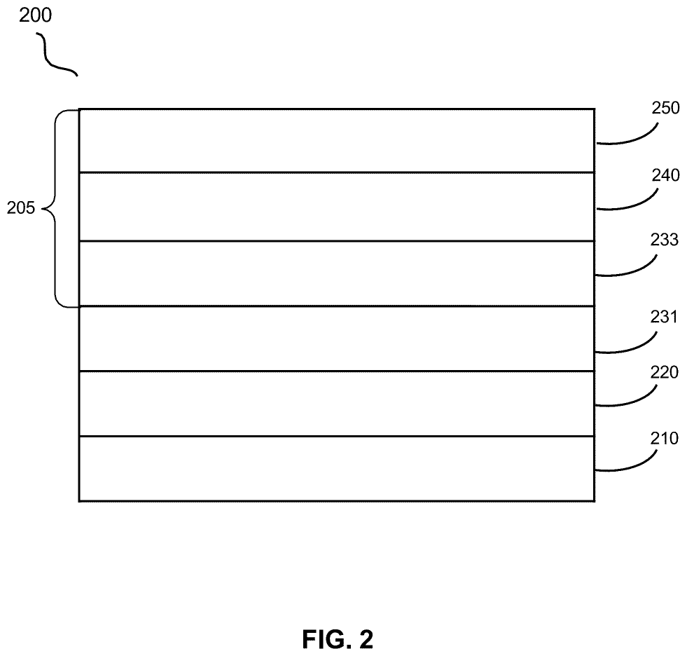

Each light-emitting structure 111a, 111b, 111c, and 121 may include light-emitting diodes, laser diodes, and/or any other suitable devices capable of producing and/or emitting light of a certain color. In some embodiments, each light-emitting structure 111a, 111b, and 111c may be configured to emit light of the first color (e.g., blue light). Light-emitting structure 121 may be configured to emit light of the second color (e.g., green light). In some embodiments, each light-emitting structure 111a, 111b, 111c, and 121 may include an n-GaN layer, a p-GaN layer, and an active layer positioned between the n-GaN layer and the p-GaN layer. The active layer may contain quantum well structures for emitting light of a certain color. In some embodiments, each light-emitting structure 111a, 111b, 111c, and 121 may include a light-emitting structure 205 as described in connection with FIG. 2. Each light-emitting structure 111a may include an active layer containing quantum well structures for emitting light of the first color (e.g., blue light). Semiconductor layer 123 may include an active layer containing quantum well structures for emitting light of the second color (e.g., green light). Each semiconductor layer 113a, 113b, 113c, and 123 may include one or more epitaxial layers of a group III-V material (e.g., GaN). In some embodiments, each semiconductor layer 113a, 113b, 113c, and 123 may include an n-GaN layer.

Apparatus 100A may include a dielectric layer 140a of a dielectric material (e.g., silicon dioxide, silicon nitride, etc.). Dielectric layer 140a may be fabricated on the top surfaces of pixels 110a-110c (e.g., the top surfaces of semiconductor layers 113a, 113b, and 123) and in the trenches separating pixels 110a-110c. Dielectric layer 140a may also cover the sidewalls of pixels 110a-110c. At least a portion of the top surface of each pixel 110a-110c (e.g., the top surfaces of semiconductor layers 113a, 113b, and 123) is not covered by dielectric layer 140a. In some embodiments, dielectric layer 140a does not cover the top surfaces of pixels 110a-110c.

Electrode layer 150a is fabricated on dielectric layer 140a and the top surfaces of pixels 110a-110c (e.g., the top surfaces of semiconductor layers 113a, 113b, and 123). As dielectric layer 140a does not cover at least a portion of the top surfaces of semiconductor layers 113a, 113b, and 123, some portions of electrode layer 150a directly contact the top surfaces of semiconductor layers 113a, 113b, and 123. Electrode layer 150a may include any suitable conductive material. In some embodiments, electrode layer 150a may include indium tin oxide (ITO) and other suitable materials to implement a transparent conductive electrode for pixels 110a-110c. In some embodiments, electrode layer 150a may be a continuous and/or substantially continuous layer of the conductive material.

Light-conversion structure 130 may be configured to convert light of the first color (e.g., light emitted by light-emitting structure 111b) into light of the third color (e.g., red light) and may be fabricated on electrode layer 150a. In some embodiments, light-conversion structure 130 may include quantum dots with emission wavelengths corresponding to light of the third color. In some embodiments, the sidewall(s) of light-conversion structure 130 may be coated with a reflective material 131. In some embodiments, the light-conversion structure 130 may include a growth template 133. Growth template 133 may be, for example, a sapphire substrate. In some embodiments, light-conversion structure 130 is bonded to electrode layer 150a via a bonding layer 170. Bonding layer 170 may include glue or any other suitable material that may bond light-conversion structure 130 to electrode layer 150a. In some embodiments, growth template 133 of apparatus 100A may be removed. In some embodiments, growth template 133 does not have to be removed if growth template 133 (e.g., a sapphire substrate) provides suitable light transmittance.

When a suitable voltage is applied to pixel 110a-110b (e.g., by applying the voltage to electrode layer 150a and/or conductive pads 1051a and 1051b), light-emitting structure 111a-111b may emit light of the first color. When a suitable voltage is applied to pixel 110c (e.g., by applying the voltage to electrode layer 150a and/or conductive pad 1051c), light-emitting structure 121 may emit light of the second color (e.g., green light). Light-emitting structure 111c does not produce light due to a short circuit caused by the presence of conductive via 115.

Apparatus 100A may further include metal sidewalls 180a, . . . , 180n that may prevent crosstalk between pixels 110a-110c. Metal sidewalls 180a, . . . , 180n may include suitable metallic material (e.g., Pt, Au, etc.) deposited on electrode layer 150a. As shown, the height of metal sidewalls 180a-180n may be higher than the height of pixels 110a and 110b. Metal sidewalls 180a-180n may be of any suitable shape. In some embodiments, the cross-section of one or more metal sidewalls 180a-180n may be a trapezoid.

Referring to FIG. 1B, apparatus 100B may include micro light-emitting devices (pixels) 110a, 110b, . . . , 110d fabricated on substrate 105. Pixels 110a, 110b, and 110d may be bonded to substrate 105 through bonding layers 107a, 107b, and 107d, respectively. In particular, pixels 110a, 110b, and 110d may be bonded to conductive pads 1051a, 1051b, . . . , and 1051d, respectively. Pixels 110a-110b, conductive pads 1051a, 1051b, . . . , and substrate 105 may be the same as their counterparts in FIG. 1A. Conductive pad 1051d and conductive pads 1051a-1051b may include any suitable conductive material. In some embodiments, conductive pad 1051d may be an interconnect of a CMOS substrate.

Pixel 110d may include a light-emitting structure 111d for emitting light of the first color, a semiconductor layer 113d, a bonding layer 117b, a light-emitting structure 125, and a semiconductor layer 127. Light-emitting structure 111d and semiconductor layer 113d may be collectively referred to as a light-emitting device 310d. Light-emitting structure 125 and semiconductor layer 127 may be collectively referred to as a light-emitting device 327 and may be bonded to semiconductor layer 113d via bonding layer 117b. Bonding layer 117b may include any suitable conductive material that may bond light-emitting structure 125 to semiconductor layer 113d and provide ohmic contact for the bottom side (e.g., the p-GaN side) of light-emitting structure 125, such as metals, alloys (e.g., an Au—Sn alloy), conductive adhesives, etc.

The sidewalls of semiconductor layer 113d and light-emitting structure 111d may be covered by a conductive layer 119 that may directly contact bonding layer 107d or establish an electrical connection to bonding layer 107d through other electrically conductive materials. Conductive layer 119 may include any suitable conductive material, such as metals, alloys (e.g., an Au—Sn alloy), conductive adhesives, etc. Conductive layer 119 may include one or more layers of the conductive material with uniform thickness or varying thicknesses. Conductive layer 119 may be regarded as part of bonding layer 117b in some embodiments.

Apparatus 100B may include a dielectric layer 140b of a dielectric material (e.g., silicon dioxide, silicon nitride, etc.). Dielectric layer 140b may be fabricated on the top surfaces of pixels 110a-110d (e.g., the top surfaces of semiconductor layers 113a, 113b, and 127) and in the trenches separating pixels 110a-110d. Dielectric layer 140b may also cover the sidewalls of pixels 110a-110d. At least a portion of the top surface of each pixel 110a, 110b, . . . , 110d (e.g., the top surfaces of semiconductor layers 113a, 113b, and 127) is not covered by dielectric layer 140b. In some embodiments, dielectric layer 140a does not cover the top surfaces of pixels 110a, 110b, . . . , 110d.

Electrode layer 150b is fabricated on dielectric layer 140b and the top surfaces of pixels 110a-110d (e.g., the top surfaces of semiconductor layers 113a, 113b, and 127). As dielectric layer 140b does not cover at least a portion of the top surfaces of semiconductor layers 113a, 113b, and 127, some portions of electrode layer 150b directly contact the top surfaces of semiconductor layers 113a, 113b, and 127. Electrode layer 150b may include any suitable conductive material. In some embodiments, electrode layer 150b may include ITO and other suitable materials to implement a transparent conductive electrode for pixels 110a-110c. In some embodiments, electrode layer 150b may be a continuous and/or substantially continuous layer of the conductive material.

When a suitable voltage is applied to pixel 110a and 110b (e.g., by applying the voltage to electrode layer 150b and/or conductive pads 1051a and 1051b), light-emitting structure 111a-111b may emit light of the first color. When a suitable voltage is applied to pixel 110d (e.g., by applying the voltage to electrode layer 150b and/or conductive pad 1051d), light-emitting structure 125 may emit light of the third color (e.g., green light, red light, etc.). Light-emitting structure 111d does not produce light because the sidewalls of light-emitting structure 111d are covered by conductive layer 119, causing a short circuit.

Apparatus 100B may further include metal sidewalls 185a, . . . , 185n that may prevent crosstalk between pixels 110a-c. Metal sidewalls 185a, . . . , 185n may include suitable metallic material (e.g., Pt, Au, etc.) deposited on electrode layer 150b. As shown, the height of metal sidewalls 185a-185n may be higher than the height of pixels 110a and 110b. Metal sidewalls 185a-185n may be of any suitable shape. In some embodiments, the cross-section of one or more metal sidewalls 185a-185n may be a trapezoid.

FIG. 2 is a diagram illustrating a cross-sectional view of an example semiconductor device 200 in accordance with some embodiments of the present disclosure.

As shown, semiconductor device 200 may include a growth template 210, a buffer layer 220, a first semiconductor layer 231 and a second semiconductor layer 233 containing a group III-V material doped with a first type of conductive impurity, an active layer 240, and a third semiconductor layer 250 containing the group III-V material doped with a second type of conductive impurity. In some embodiments, second semiconductor layer 233, active layer 240, and third semiconductor layer 250 may also be referred to as light-emitting structure 205.

Growth template 210 may include one or more epitaxial layers of the group III-V material (e.g., gallium nitride (GaN)) to be grown on the growth template 210 and/or a foreign substrate. The foreign substrate may contain any other suitable crystalline material that can be used to grow the group III-V material, such as sapphire, silicon carbide (SiC), silicon (Si), quartz, gallium arsenide (GaAs), aluminum nitride (AlN), etc.

Buffer layer 220 may include one or more epitaxial layers of the group III-V material (e.g., GaN) that are not doped with any particular conductive type of impurity.

First semiconductor layer 231 and second semiconductor layer 233 may include one or more epitaxial layers of group III-V materials and any other suitable semiconductor material (e.g., GaN) doped with the first type of conductive impurity. The first type of conductive impurity may be an n-type impurity in some embodiments. For example, each of first semiconductor layer 231 and second semiconductor layer 233 may include an n-GaN layer (e.g., a Si-doped GaN layer, a Ge-doped GaN layer, etc.). In some embodiments, first semiconductor layer 231 and second semiconductor layer 233 may be one epitaxial layer of n-GaN. In some embodiments, first semiconductor layer 231 and second semiconductor layer 233 may be multiple n-GaN layers and may or may not contain the same n-doped GaN.

Active layer 240 may include one or more layers of semiconductor materials and/or any other suitable material for producing light. For example, active layer 240 may include one or more quantum well structures for producing light. Each of the quantum well structures may be and/or include a single quantum well structure (SQW) and/or a multi-quantum well (MQW) structure. Each of the quantum well structures may include one or more quantum well layers and barrier layers (not shown). The quantum well layers and barrier layers may be alternately stacked on one another. The quantum well layers may include indium (e.g., indium gallium nitride). Each of the quantum well layers may be an undoped layer of indium gallium nitride (InGaN) that is not intentionally doped with impurities.

Each of the barrier layers may be an undoped layer of the group III-V material that is not intentionally doped with impurities. A pair of a barrier layer (e.g., a GaN layer) and a quantum well layer (e.g., an InGaN layer) may be regarded as being a quantum well structure. Active layer 240 may contain any suitable number of quantum well structures. For example, the number of the quantum well structures (e.g., the number of pairs of InGaN and GaN layers) may be 3, 4, 5, etc. The material composition and/or the layer structures of the quantum well layers may vary to emit different colors of light. For example, the proportion of indium in the InGaN layer is higher for green LEDs compared to blue LEDs. In one implementation, active layer 240 may include suitable quantum well structures for emitting blue light. In another implementation, active layer 240 may include suitable quantum well structures for emitting green light. In yet another implementation, active layer 240 may include suitable quantum well structures for emitting red light.

Third semiconductor layer 250 may include one or more epitaxial layers of the group III-V material and/or any other suitable material. For example, third semiconductor layer 250 can include an epitaxial layer of the group III-V material doped with a second conductive type impurity that is different from the first conductive type impurity. For example, the second conductive type impurity may be a p-type impurity. In some embodiments, third semiconductor layer 250 may include a GaN layer doped with magnesium.

When energized, active layer 240 may produce and emit light. For example, when an electrical current passes through active layer 240, electrons from semiconductor layer 233 (e.g., an n-doped GaN layer) may combine in active layer 240 with holes from third semiconductor layer 250 (e.g., a p-doped GaN layer). The combination of the electrons and the holes may result in the emission of light. In some embodiments, the active layer 240 may produce light of a certain color (e.g., light with certain wavelengths).

While certain layers of semiconductor materials are shown in FIG. 2, this is merely illustrative. For example, one or more intervening layers may or may not be formed between two semiconductor layers of FIG. 2 (e.g., between semiconductor layer 233 and active layer 240, between active layer 240 and third semiconductor layer 250, etc.). In one implementation, a surface of second semiconductor layer 233 may directly contact a surface of active layer 240. In another implementation, one or more intervening layers (not shown in FIG. 2) may be formed between second semiconductor layer 233 and active layer 240. One or more intervening layers (not shown in FIG. 2) may be formed between first semiconductor layer 231 and buffer layer 220.

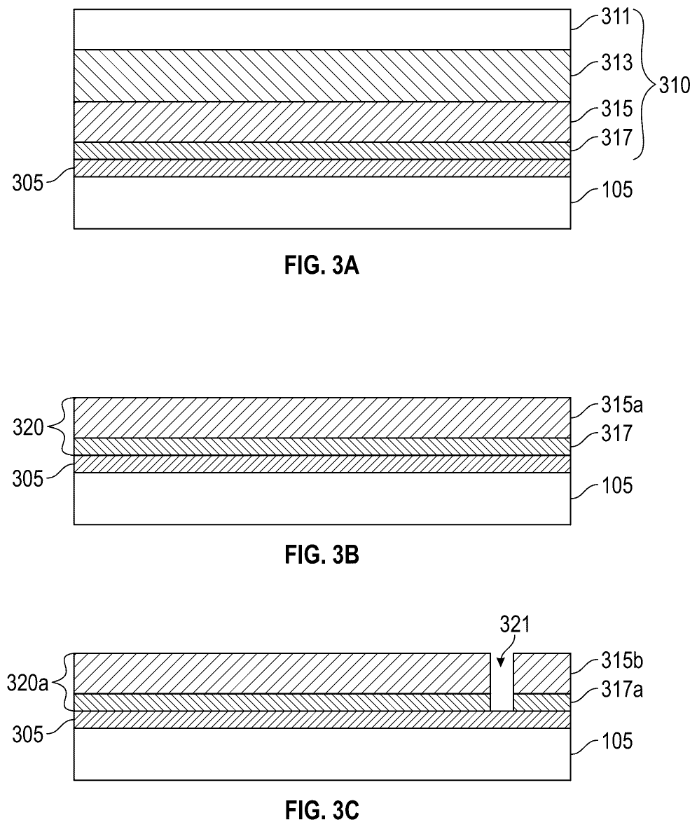

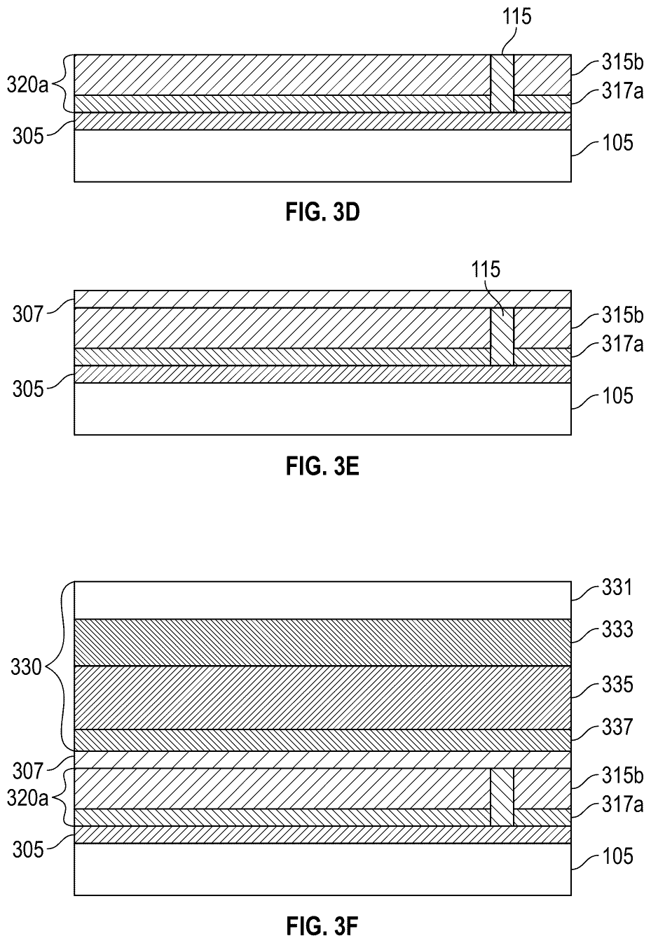

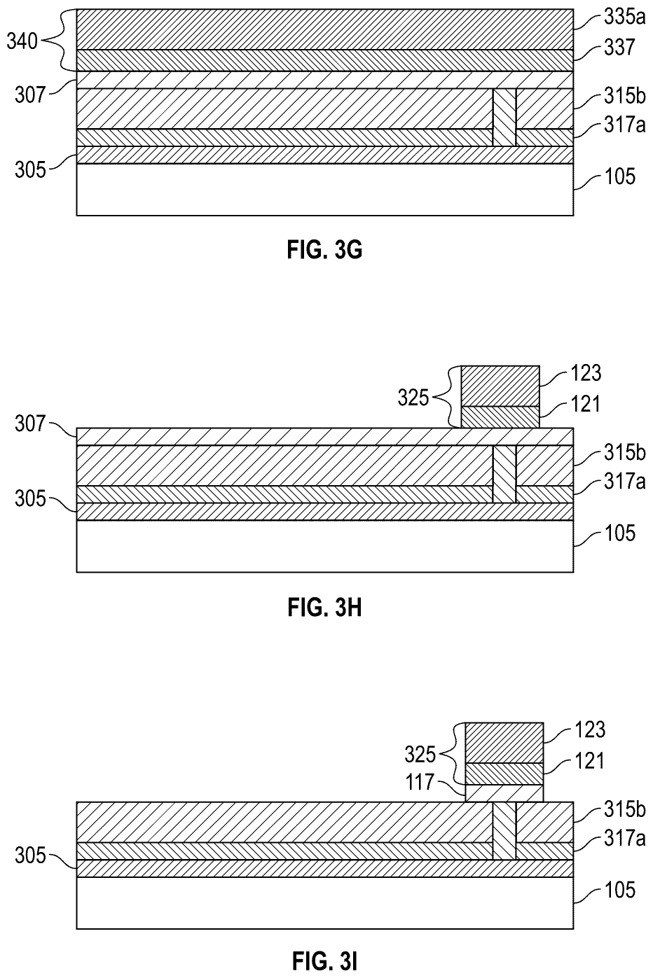

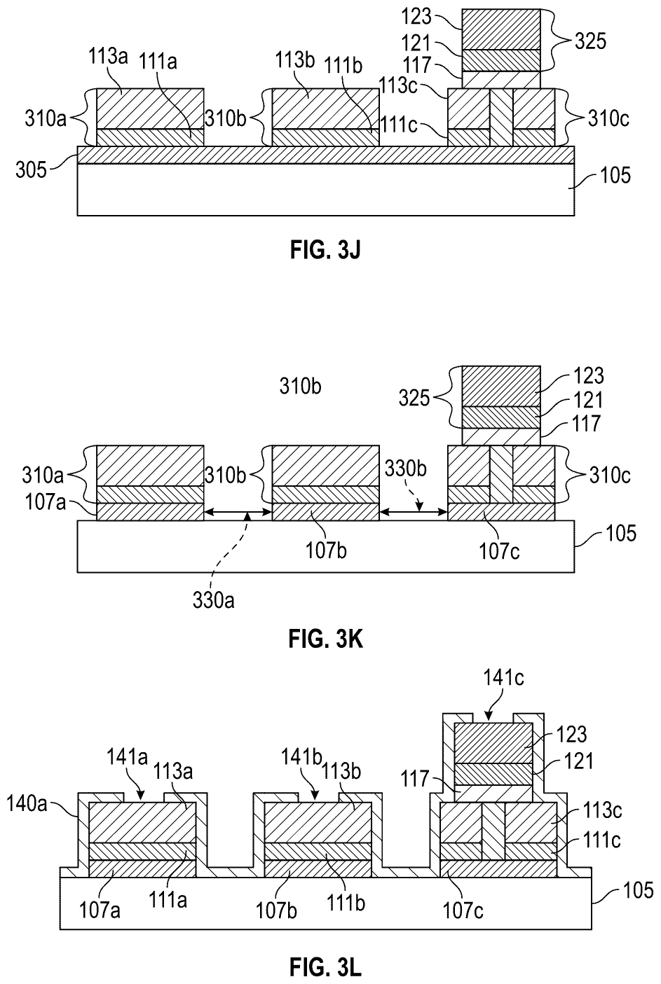

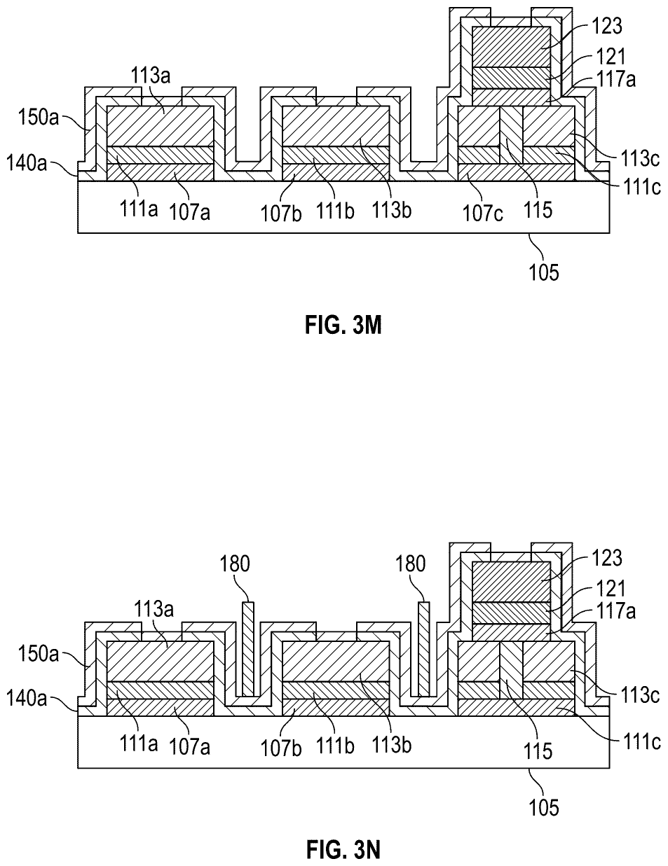

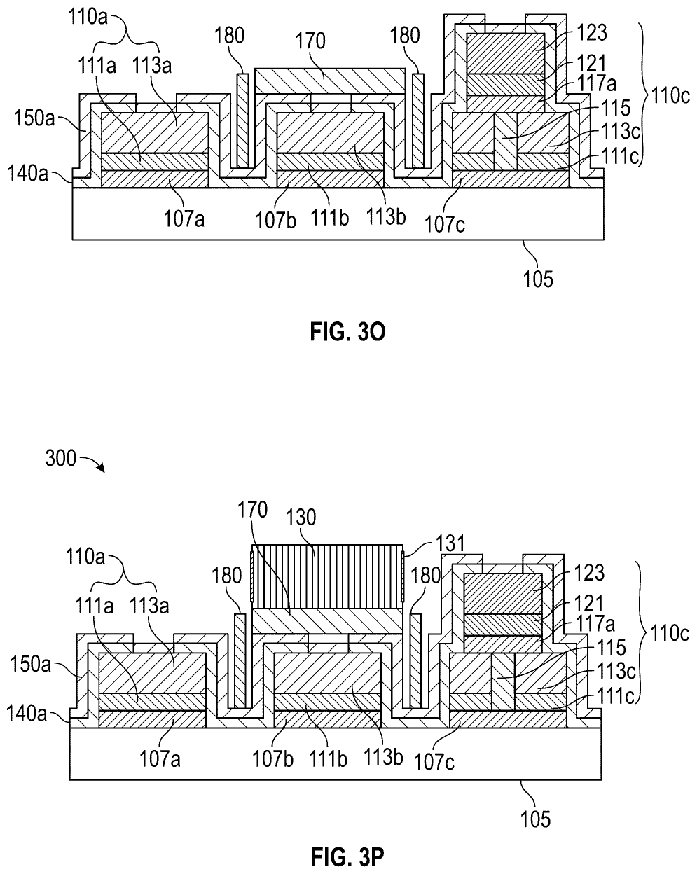

FIGS. 3A, 3B, 3C, 3D, 3E, 3F, 3G, 3H, 3I, 3J, 3K, 3L, 3M, 3N, 3O, and 3P are schematic diagrams illustrating cross-sectional views of structures related to a process for fabricating an apparatus incorporating micro-LEDs in accordance with some embodiments of the present disclosure.

As shown in FIG. 3A, a semiconductor device 310 may be bonded to substrate 105. Semiconductor device 310 may include a growth template 311, a buffer layer 313, a semiconductor layer 315, and a light-emitting structure 317. Semiconductor layer 315 may contain one or more epitaxial layers of a group III-V material. In some embodiments, semiconductor layer 315 may include one or more n-GaN layers. Light-emitting structure 317 may include an n-GaN layer, an active layer, and a p-GaN layer. Light-emitting structure 317 may be light-emitting structure 205 of FIG. 2. Growth template 311, buffer layer 313, and semiconductor layer 315 may correspond to growth template 210, buffer layer 220, and first semiconductor layer 231 of FIG. 2, respectively.

Semiconductor device 310 may be bonded to substrate 105 via a bonding layer 305 (e.g., utilizing a metal bonding or any other suitable bonding process). In some embodiments, a p-GaN layer of light-emitting structure 317 may be bonded to substrate 105 via bonding layer 305.

As shown in FIG. 3B, one or more portions of semiconductor device 310 may be removed to expose a surface of semiconductor layer 315. For example, growth template 311 and buffer layer 313 may be removed (e.g., utilizing ICP (inductively coupled plasma) etching techniques). Semiconductor layer 315 may be thinned (e.g., using ICP techniques). The thinned first semiconductor layer 315 may be referred to as semiconductor layer 315a. Semiconductor layer 315a and light-emitting structure 317 may be collectively referred to as light-emitting stack 320.

As shown in FIG. 3C, one or more portions of light-emitting stack 320 may be removed to expose one or more portions of the top surface of bonding layer 305. In particular, semiconductor layer 315a and light-emitting structure 317 may be patterned and etched to form an opening 321 in light-emitting stack 320. In some embodiments, a dimension (e.g., the height) of opening 321 may be about 1 μm. The etched semiconductor layer 315a is referred to as semiconductor layer 315b. The etched light-emitting structure 317 may be referred to as light-emitting structure 317a. Semiconductor layer 315b and light-emitting structure 317a may be collectively referred to as light-emitting stack 320a.

As shown in FIG. 3D, one or more suitable conductive materials (e.g., metals) may be deposited in opening 321 to form a conductive via 115 in light-emitting stack 320a. In some embodiments, conductive via 115 may be a metal via (e.g., a Cu via).

As shown in FIG. 3E, a bonding layer 307 may be fabricated on the top surface of semiconductor layer 315a and conductive via 323. Bonding layer 307 may include any suitable material that may bond the structures to be formed on semiconductor layer 315a to semiconductor layer 315a and provide ohmic contact. In some embodiments, bonding layer 307 may include a layer of an Au—Sn alloy, indium, etc.

As shown in FIG. 3F, a semiconductor device 330 may be bonded to light-emitting stack 320a and conductive via 323 through bonding layer 307. Semiconductor device 330 may include a growth template 331, a buffer layer 333, a semiconductor layer 335, and a light-emitting structure 337. Light-emitting structure 337 may include an n-GaN layer, an active layer, and a p-GaN layer. Light-emitting structure 337 may be light-emitting structure 205 of FIG. 2. Growth template 331, buffer layer 333, and semiconductor layer 335 may correspond to growth template 210, buffer layer 220, and first semiconductor layer 231 of FIG. 2, respectively.

As shown in in FIG. 3G, growth template 331 and buffer layer 333 may be removed. Semiconductor layer 335 may be thinned. The thinned semiconductor layer 335 may be referred to as semiconductor layer 335a. Semiconductor layer 335a and light-emitting structure 337 may be collectively referred to as light-emitting stack 340.

As shown in FIG. 3H, one or more portions of light-emitting stack 340 may be selectively removed to fabricate a light-emitting device 325 for emitting light of the second color (e.g., green light). For example, semiconductor layer 335a may be patterned and etched to fabricate a semiconductor layer 123. Light-emitting structure 337 may be patterned and etched to fabricate a light-emitting structure 121. Light-emitting device 325 may be a micro-LED.

As shown in FIG. 3I, one or more portions of bonding layer 307 may be selectively removed to form bonding layer 117. Light-emitting device 325 and light-emitting structure 121 may be bonded to semiconductor layer 315b via bonding layer 117.

Referring to FIG. 3J, one or more portions of light-emitting stack 320a may be selectively removed to fabricate a plurality of light-emitting devices 310a, 310b, . . . , 310c. Each light-emitting device 310a, 310b, . . . , 310c may be a micro-LED. Semiconductor layer 315a may be patterned and etched to form semiconductor layers 113a, 113b, . . . , 113c. The patterning and etching of light-emitting structure 317 may form light-emitting structures 111a, 111b, . . . , 111c. Light-emitting device 325 and light-emitting structure 121 may be bonded to light-emitting device 310c via bonding layer 117.

As shown in FIG. 3K, one or more portions of bonding layer 305 may be selectively removed to expose multiple portions of a top surface of substrate 105 and to form bonding layers 107a, 107b, . . . , 107c. Light-emitting structures 111a, 111b, . . . , 111c may be bonded to substrate 105 via bonding layers 107a, 107b, . . . , 107c, respectively. As shown in FIGS. 3J-3K, the selective etching of light-emitting stack 320a and bonding layer 305 may create a plurality of trenches 330a, . . . , 330b that separate bonding layers 107a-107c and light-emitting devices 310a-c.

As shown in FIG. 3L, a dielectric layer 140a may be fabricated on light-emitting devices 310a, 310b, and 325, and in trenches 320a-320b. Dielectric layer 140a may include a layer of one or more suitable dielectric materials, such as SiO₂, Si₃N₄, etc. Dielectric layer 140a may cover the sidewalls of bonding layers 107a-c, light-emitting structure 111a-c, semiconductor layers 113a-c, bonding layer 117, light-emitting structure 121, and semiconductor layer 123. Dielectric layer 140a may be and/or include a layer of a dielectric material (e.g., silicon oxide, silicon nitride, etc.) with openings 141a, 141b, . . . , 141c. Openings 141a, 141b, . . . , 141c may expose at least a portion of the top surfaces of light-emitting devices 310a, 310b, and 325 (e.g., the top surfaces of semiconductor layers 113a, 113b, . . . , 123), respectively.

As shown in FIG. 3M, electrode layer 150a may be fabricated on dielectric layer 140a and the portions of the top surfaces of light-emitting devices 310a, 310b, and 325 (e.g., the top surfaces of semiconductor layers 113a, 113b, . . . , 123) that are not covered by dielectric layer 140a (e.g., openings 141a, 141b, . . . , 141c).

As shown in FIG. 3N, metal sidewalls 180a-180n may be fabricated on the portions of electrode layer 150a that are deposited in trenches 330a-b.

As shown in FIG. 3O, bonding layer 170 may be fabricated on the portion of electrode layer 150a that is formed on semiconductor layers 113b. A light-conversion structure 130 may be bonded to the top surface of semiconductor layer 113b via bonding layer 170 to form apparatus 100A as described in connection with FIG. 1A.

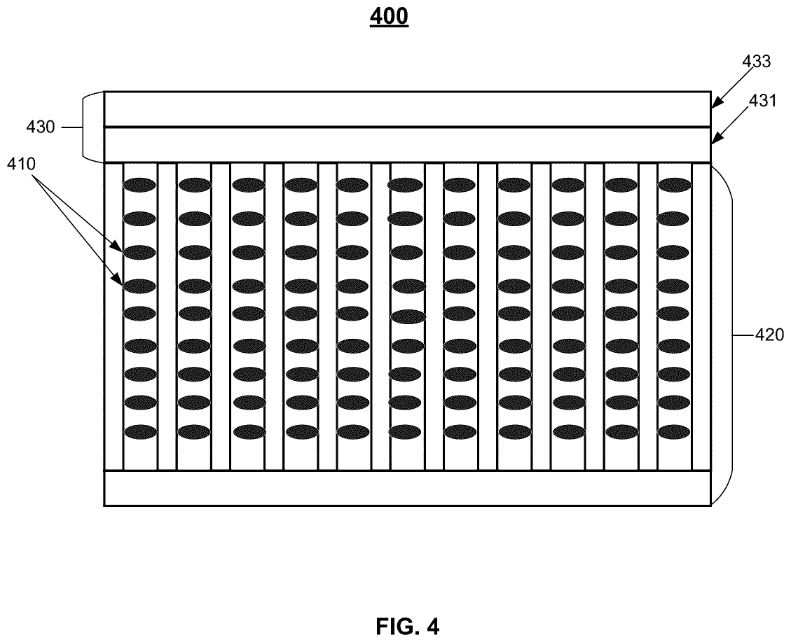

Referring to FIG. 3P, light-conversion structure 130 may be bonded to a portion of electrode layer 150a that covers light-emitting device 310b through bonding layer 170. Light-conversion structure 130 may include any suitable component for converting light emitted by light-emitting device 310b into light of a third color (e.g., red light). For example, light-conversion structure 130 may include quantum dots that may convert the light-emitting by light-emitting device 310b into light of the third color. As a more particular example, light-conversion structure 130 may include a light-conversion structure 400 as described in connection with FIG. 4. As another more particular example, light-conversion structure 130 may include a film containing quantum dots. As another example, light-conversion structure 130 may phosphor materials, photoluminescent materials, etc. that may convert the light-emitting by light-emitting device 310b into light of the third color.

As shown in FIGS. 1A, 1B, and 3P, apparatus 100A, apparatus 100B, and apparatus 300 may include a first pixel configured to emit light of a first color (pixel 110a), a second pixel configured to emit light of a second color (pixel 110c or 110d), and a third pixel configured to emit light of a third color (pixel 110b). Each apparatus 100A, apparatus 100B, and apparatus 300 may include a plurality of light-emitting devices for emitting light of the first color (e.g., light-emitting device 310a, 310b, 310c, 310d, etc.) and a light-emitting device for emitting light of the second color (e.g., light-emitting device 325, light-emitting device 327, etc.). Each of the plurality of light-emitting devices for emitting light of the first color (e.g., light-emitting device 310a, 310b, 310c, 310d, etc.) may be bonded to substrate 105 and a conductive pad (e.g., conductive pads 1051a, 1051b, 1051c, 1051d, etc.). The light-emitting device for emitting light of the second color is fabricated on a first light-emitting device (e.g., light-emitting device 310c or light-emitting device 310d) of the plurality of light-emitting devices for emitting light of the first color. The first light-emitting device of the plurality of light-emitting devices for emitting light of the first color may be bonded to a conductive pad (e.g., conductive pad 1051c or 1051d). The light-emitting device for emitting light of the second color may be electrically connected to the conductive pad. Each apparatus 100A, apparatus 100B, and apparatus 300 may further include a light-conversion structure (e.g., light-conversion structure 130) that may convert light emitted by a second light-emitting device (e.g., light-emitting device 310b) of the plurality of light-emitting devices for emitting light of the first color into light of the third color.

While a certain number of pixels are fabricated on substrate 105 as described above, this is merely illustrative. The operations described in connection with FIGS. 3A-3P may be performed to fabricate multiple sets of red pixels, green pixels, and blue pixels on substrate 105.

FIG. 4 is a schematic diagram illustrating an example 400 of a light-conversion structure in accordance with some embodiments of the present disclosure.

As shown, light-conversion structure 400 may include quantum dots (QDs) 410 placed in a nanoporous structure 420. QDs 410 may be and/or include semiconductor particles in nanoscale sizes, such as one or more of ZnS, ZnSe, CdSe, InP, CdS, PbS, InP, InAs, GaAs, GaP, etc. QDs 410 may have emission wavelengths corresponding to light of a certain color (e.g., red light, green light, etc.).

Nanoporous structure 420 may include nanoporous materials containing pores with a nanoscale size (e.g., a size of the order of 1 nm to 1000 nm or larger. The nanoporous materials may include semiconductor materials (Si, GaN, AlN, etc.), glass, plastic, metal, polymer, etc. In some embodiments, nanoporous structure 420 may be grown on a growth template (not shown in FIG. 4). For example, nanoporous structure 420 may include porous n-GaN layers growing on a sapphire substrate, a silicon substrate, etc.

Light-conversion structure 400 may further include a protection structure 430. The protection structure may include one or more materials (e.g., organic materials, inorganic materials) and may protect the QDs from oxygen, water, moisture, and/or other environmental factors. The protection structure may also prevent chemical degradation of the QDs and may enhance the stability of the light conversion device.

In some embodiments, protection structure 430 may include a first protection layer 431 that covers the surfaces of the QDs placed in the nanoporous structure. The first protection layer 431 may be and/or include a coating on surfaces of the QDs in the nanoporous structure. As an example, protection layer 431 can be formed by spinning coating or spraying the liquid-phase of the protection layer on the surface of porous structure. The liquid-phase protection layer can then flow inside the nanoporous structure. The coating may include one or more suitable materials that may prevent oxidation of the QDs and/or protect the QDs from other environmental factors, such as polydimethylsiloxane (PDMS), poly (methylmethacrylate) (PMMA), epoxy, etc. In some embodiments, as shown in FIG. 4, protection layer 431 may also include a layer of the first material formed on the nanoporous structure. It is to be noted that the coating that covers the QDs is not shown in FIG. 4.

Protection structure 430 may further include a protection layer 433 (also referred to as the “second protection layer”). The protection layer 433 may include one or more materials that may protect the QDs from oxygen, moisture, and/or other environmental factors. For example, protection layer 433 may include one or more layers of SiO₂, SiN, Al₂O₃, PDMS, PMMA, etc. Protection layer 433 may be formed on protection layer 431 to provide further protection for the QDs in the light-conversion structure. The protection layers 431 and 433 may or may not contain the same material.

In one implementation, protection layer 431 and/or the coating of the QDs include a first material. Protection layer 433 includes a second material that is different from the first material. Examples of the first material may include PDMS, PMMA, epoxy, etc. Examples of the second material may include SiO₂, SiN, Al₂O₃, etc. In another implementation, protection layers 431 and 433 and/or the coating of the QDs may include a common material.

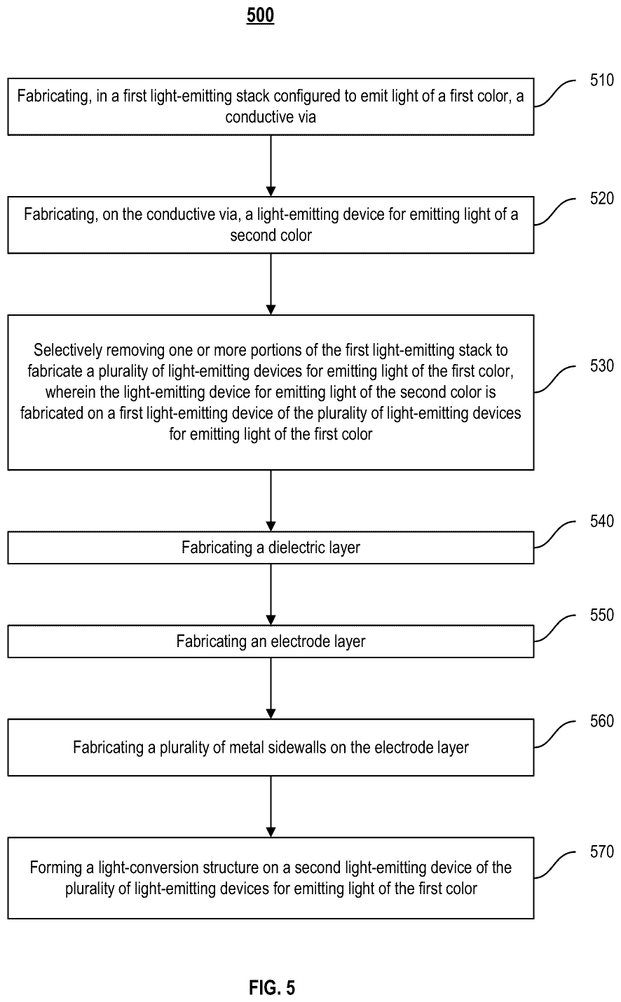

FIG. 5 is a flow diagram illustrating an example 500 of a process for fabricating an apparatus incorporating pixels in accordance with some embodiments of the present disclosure.

At 510, a conductive via may be fabricated in a first light-emitting stack. The first light-emitting stack may include any suitable components for emitting light of a first color (e.g., blue light). For example, the first light-emitting stack may include a plurality of epitaxial layers of a group III-V material (e.g., GaN) and an active layer including quantum well structures for emitting light of the first color. In some embodiments, the first light-emitting stack may be light-emitting stack 320 of FIG. 3B and may include semiconductor layer 315a and light-emitting structure 317. In some embodiments, the first light-emitting stack may be bonded to a substrate as described in connection with FIGS. 3A-3B above.

Fabricating the conductive via may involve creating an opening (e.g., opening 321 of FIG. 3C) in the first light-emitting stack. A metallic material may then be deposited in the opening. In some embodiments, a layer of the metallic material that is thicker than the depth of the opening may be deposited to fill the opening, and the extra metallic material deposited on the first light-emitting stack may be removed (e.g., using chemical mechanical planarization processes).

At 520, a light-emitting device for emitting light of a second color may be fabricated on the conductive via and the first light-emitting stack. For example, a second light-emitting stack (e.g., light-emitting stack 340 of FIG. 3G) may be bonded to the first light-emitting stack and the conductive via through a bonding layer containing conductive bonding materials (e.g., Au, Sn, In, Ag, Ti, Pt, Ni, Al, etc.). The second light-emitting stack may be bonded to the first light-emitting stack and the conductive via using metallic bonding techniques. The second light-emitting stack may include suitable structures for emitting light of the second color. One or more portions of the second light-emitting stack may be selectively removed to form the light-emitting device for emitting light of the second color. For example, the second light-emitting stack may be patterned and etched using photolithography and ICP etching techniques. The light-emitting device for emitting light of the second color may be, for example, light-emitting device 325 of FIG. 3H and may be fabricated by performing operations as described in connection with FIGS. 3E-3I above.

At 530, a plurality of light-emitting devices may be fabricated by selectively removing one or more portions of the first light-emitting stack. For example, the first light-emitting stack may be patterned and etched (e.g., using photolithography and ICP etching techniques) to form light-emitting structures (e.g., the light-emitting structures 111a, 111b, . . . , 111c of FIG. 3J) for emitting light of the first color. The light-emitting device for emitting light of the second color (e.g., light-emitting device 325 of FIG. 3J) is fabricated on a first light-emitting device of the plurality of light-emitting devices for emitting light of the first color (e.g., light-emitting device 310c of FIG. 3J).

At 540, a dielectric layer may be fabricated. For example, one or more dielectric materials may be deposited in the trenches that separate the plurality of light-emitting devices for emitting the first color. The dielectric layer may be the dielectric layer 140a as described in connection with FIG. 3L above.

At 550, an electrode layer may be fabricated on the dielectric layer. Fabricating the electrode layer may involve depositing a layer of ITO or any other suitable conductive material. The electrode layer may be the electrode layer 150a of FIG. 1A and may be fabricated as described in connection with FIG. 3M.

At 560, a plurality of metal sidewalls may be fabricated. For example, metal sidewalls 180 may be fabricated on the portions of electrode layer 150a that are deposited in trenches 330a-b as described in connection with FIG. 3N.

At 570, a light-conversion structure may be fabricated on a second light-emitting device of the plurality of light-emitting devices for emitting light of the first color. The light-conversion structure may convert light of the first color into light of a third color (e.g., converting blue light into red light). In one implementation, the light-conversion structure may be bonded to the second light-emitting structure for emitting light of the first color (e.g., by performing operations as described in connection with FIGS. 3O, 1, and/or 3P). In another implementation, the light-conversion structure may be formed by fabricating the nanoporous structure on the second light-emitting structure and placing the quantum dots in the nanoporous structure.

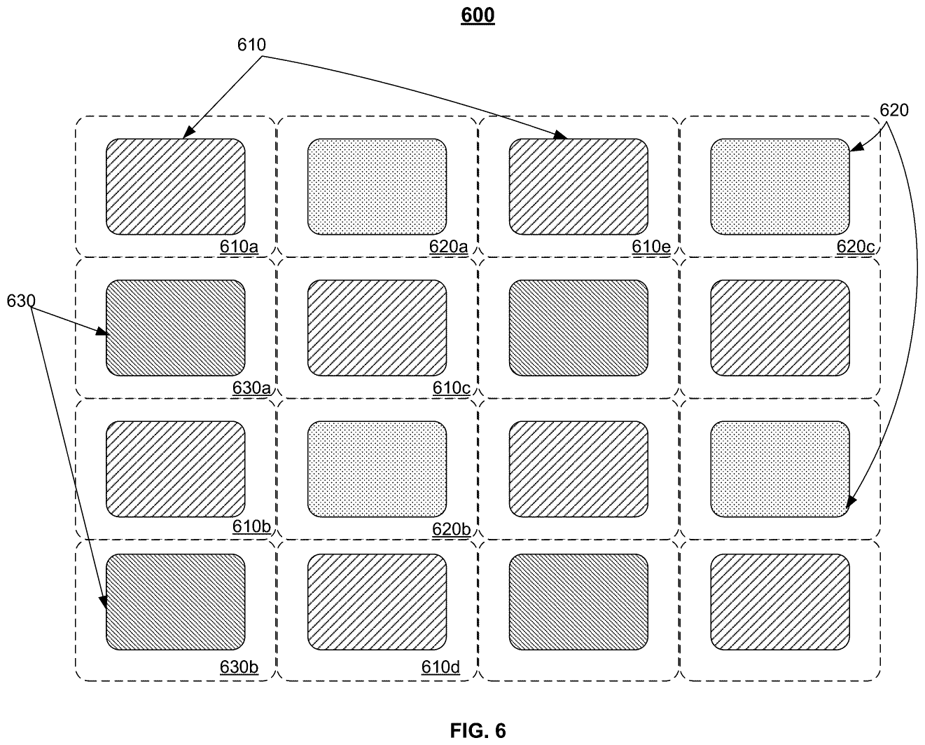

FIG. 6 depicts a schematic diagram illustrating an example pixel arrangement of an example display device 600 in accordance with some embodiments of the present disclosure. Display device 600 may be incorporated into any suitable computing device, such as mobile phones, laptops, desktops, tablet computer devices, wearable computing devices (e.g., watches, eyeglasses, head-mounted displays, virtual reality headsets, activity trackers, clothing, contact lenses, etc.), televisions, etc. Display device 600 may be of any suitable size. Display device 600 may include one or more apparatuses 100A and/or 100B as described in connection with FIGS. 1A-1B above.

As illustrated, display device 600 may include an array of red pixels 610, green pixels 620, and blue pixels 630. The array may contain any suitable number of red pixels, green pixels, and blue pixels to implement a display of a desirable size and/or resolution. In the array, red pixels 610, green pixels 620, and blue pixels 630 are arranged such that along a first direction of the array, each row contains either a combination of red pixels and blue pixels or a combination of red pixels and green pixels. None of the rows of the array contain combinations of all three types of pixels (i.e., red pixels, blue pixels, and green pixels). Similarly, in a second direction, each column of the array includes either a combination of red pixels and green pixels or a combination of red pixels and blue pixels. None of the columns of the array contain combinations of all three types of pixels (i.e., red pixel, blue pixels, and green pixels). For example, red pixels 610a, 610b, . . . , 610c and blue pixels 630a-630b may be arranged in the first column of the array. The first column of the array does not include any green pixel. As another example, the second column of the array may include red pixels 610c-610d and green pixels 620a-620b, but does not include any blue pixels. The first row of the array includes red pixels 610a-610e and green pixels 620a-620c, but does not include any blue pixels. The arrangement of the red pixels, the green pixels, and the blue pixels may prevent and/or eliminate optical crosstalk between pixels of different colors.

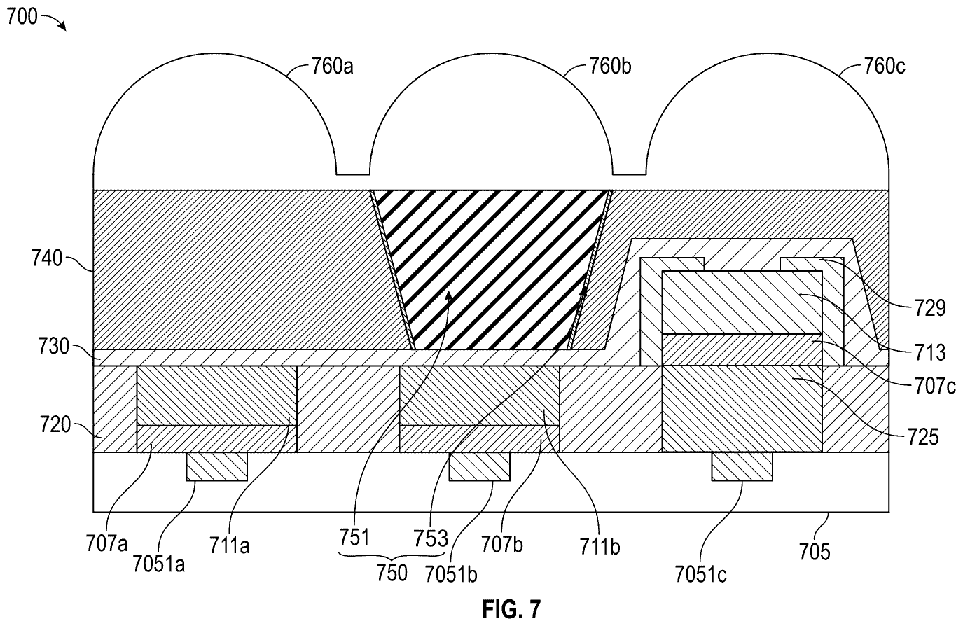

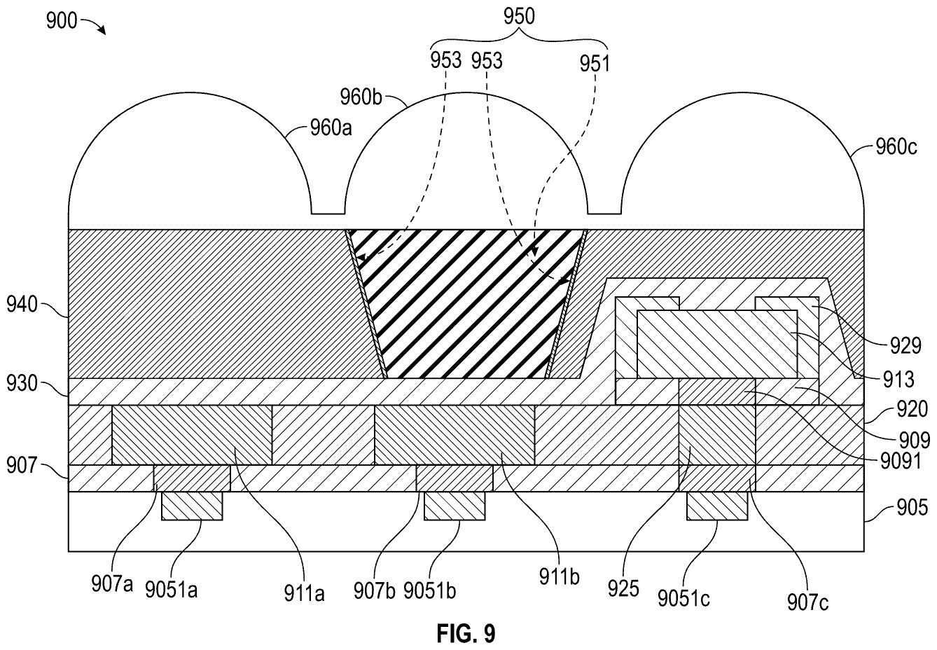

Each of red pixels 610, green pixels 620, and blue pixels 630 may include a pixel as described in connection with FIGS. 1A-1B. As an example, each blue pixel 630 may include a pixel 110a of FIGS. 1A-1B. In one implementation, one or more red pixels 610 may include a light-emitting structure for emitting blue light and a light-conversion structure for converting blue light into red light. For example, one or more red pixels 610 may include pixel 110b of FIGS. 1A-1B. As another example, one or more red pixels 610 may include a light-emitting device 711b and a light-conversion structure 750 of FIG. 7. As a further example, one or more red pixels 610 may include a light-emitting device 911b and a light-conversion structure 950 of FIG. 9. In another implementation, one or more red pixels 610 may include a light-emitting structure for emitting red light (e.g., an AlGaInP red micro-LED). The light-emitting structure for emitting red light may be fabricated on a light-emitting structure for emitting blue light (e.g., by bonding the light-emitting structure for emitting red light to the light-emitting structure for emitting blue light).

One or more green pixels 620 may include a light-emitting structure for emitting green light. The light-emitting structure for emitting green light may be fabricated on a light-emitting structure for emitting blue light. The light-emitting structure for emitting green light may be bonded to the light-emitting structure through suitable bonding materials that are electrically conductive. When a suitable voltage is applied to the green pixel 630, the light-emitting structure for emitting blue light does not emit light due to a short circuit, and the light-emitting structure for emitting green light may emit green light. For example, one or more green pixels 620 may include pixel 110c of FIG. 1A and/or pixel 110d of FIG. 1B. As another example, one or more green pixels 620 may include a light-emitting device 713 of FIG. 7 or a light-emitting device

In some embodiments, red pixels 610, green pixels 620, and blue pixels 630 may be fabricated utilizing the methods described above in connection with FIGS. 1A-5 and 7-11.

Display device 600 may include a substrate (not shown). The substrate may include any suitable component for supporting pixels and/or any other suitable component of display device 600. In one implementation, the substrate may include a driver circuit (e.g., one or more CMOS drivers, a TFT, etc.). In another implementation, the substrate does not include a driver circuit. The substrate may include a plurality of conductive lines (e.g., rows and/or columns of conductive lines) connecting one or more of the pixels disposed on the substrate.

FIG. 7 is a diagram illustrating a cross-sectional view of an example apparatus 700 incorporating micro-LEDs in accordance with some embodiments of the present disclosure.

As shown, apparatus 700 may include light-emitting devices 711a, . . . , 711b for emitting light of a first color (e.g., blue light). Light-emitting devices 711a, . . . , 711b may be fabricated on a substrate 705. For example, light-emitting devices 711a and 711b may be bonded to substrate 705 through conductive bonding layers 707a and 707b, respectively. Substrate 705 may be the substrate 105 in FIG. 1A. Conductive pads 7051a, 7051b, and 7051c may include any suitable conductive bonding material, such as an Au—Sn alloy, indium, etc. In some embodiments, substrate 705 may be a CMOS substrate, and conductive pad 7051a-7051c may be interconnects of the CMOS substrate. Light-emitting devices 711a and 711b may be bonded to conductive pads 7051a and 7051b, respectively.

Each light-emitting device 711a-711b may include a light-emitting structure 205 as described in connection with FIG. 2 above. The light-emitting devices 711a-711b for emitting the first color and the conductive via 725 may be separated by a first dielectric layer 720. Conductive via 725 may include any suitable conductive material, such as metals (e.g., Cu, Au, Al, etc.), alloys, conductive nitrides (e.g., titanium nitride (TiN), tantalum nitride (TaN), tungsten nitride (WNₓ), etc.)

Apparatus 700 may further include a light-emitting device 713 for emitting light of a second color (e.g., green light). Each of light-emitting devices 711a, 711b, and 713 may be a micro-LED in some embodiments. Light-emitting device 713 may be bonded to a conductive via 725 via a conductive bonding layer 707c. As such, light-emitting device 713 is electrically connected to conductive pad 7051c via conductive bonding layer 707c and conductive via 725.

The sidewalls and one or more portions of the top surface of the light-emitting device 713 may be covered by one or more dielectric materials 729. At least a portion of the top surface of the light-emitting device 713 is not covered by the dielectric material 729 and may directly contact an electrode layer 730 or be electrically connected to electrode layer 730 in another manner. Electrode layer 730 may contain transparent conductive materials, such as ITO. Electrode layer 730 may provide ohmic contact for light-emitting devices 711a, 711b, . . . , 713. In some embodiments, electrode layer 730 may directly contact the top surfaces of light-emitting devices 711a and 711b.

A second dielectric layer 740 may be fabricated on electrode layer 730. The second dielectric layer may include any suitable dielectric material, such as SiO₂, Si₃N₄, etc.

A light-conversion structure 750 may be fabricated in second dielectric layer 740. The light-conversion structure 750 may include quantum dots 751 for converting light of the first color into light of a third color. In some embodiments, quantum dots 751 may convert blue light into red light. In some embodiments, light-conversion structure 750 may be a via fabricated in second dielectric layer 740 embedded with quantum dots 751. The sidewalls of light-conversion structure 750 may be coated with one or more reflective materials 753.

Apparatus 700 may further include micro-lenses 760a, 760b, and 760c fabricated on light-conversion structure 750 and second dielectric layer 740. Micro-lenses 760a, 760b, and 760c may enhance the extraction and directionality of the light emitted by light-emitting devices 711a, 711b, and 713. In particular, micro-lens 760a may be fabricated on a portion of second dielectric layer 740 covering light-emitting device 711a and may enhance the extraction and directionality of the light produced by light-emitting device 711a (e.g., blue light). Micro-lens 760b may be fabricated on light-conversion structure 750 and may enhance the extraction and directionality of the light produced by light-conversion structure 750 (e.g., the red light). Micro-lens 760c may be fabricated on a portion of second dielectric layer 740 that covers light-emitting device 713 and may enhance the extraction and directionality of the light produced by light-emitting device 713 (e.g., green light).

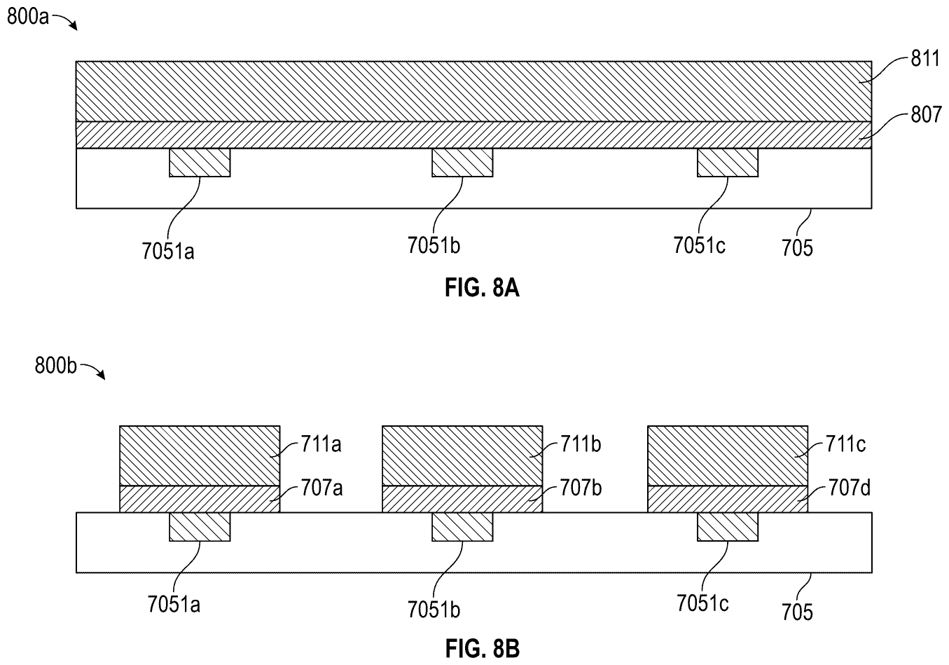

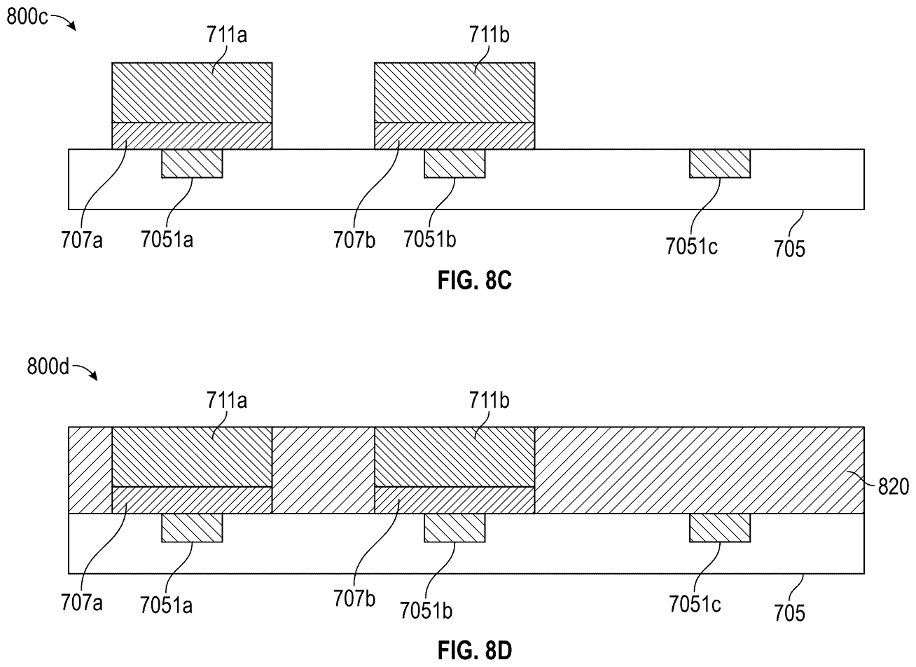

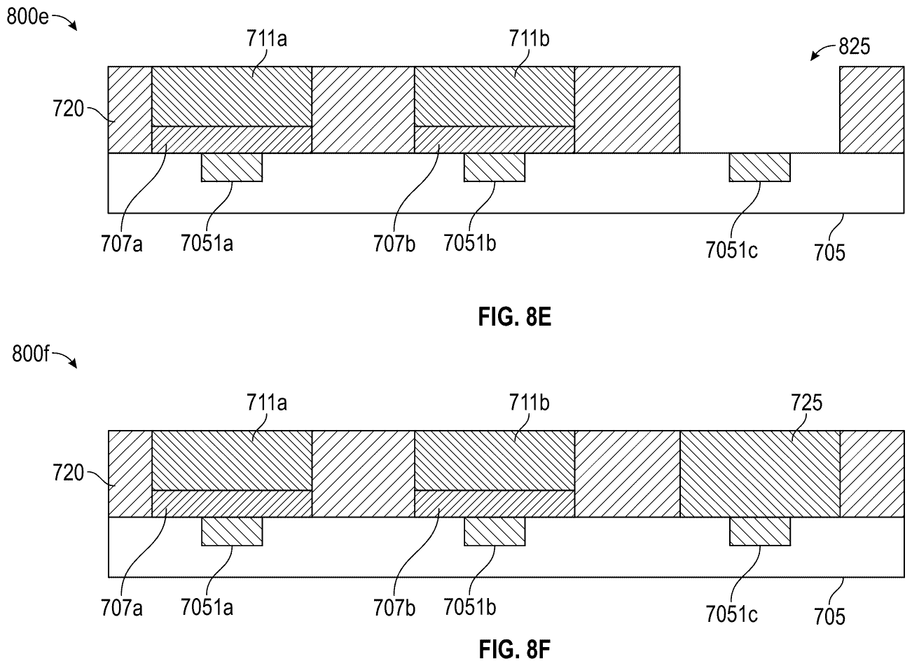

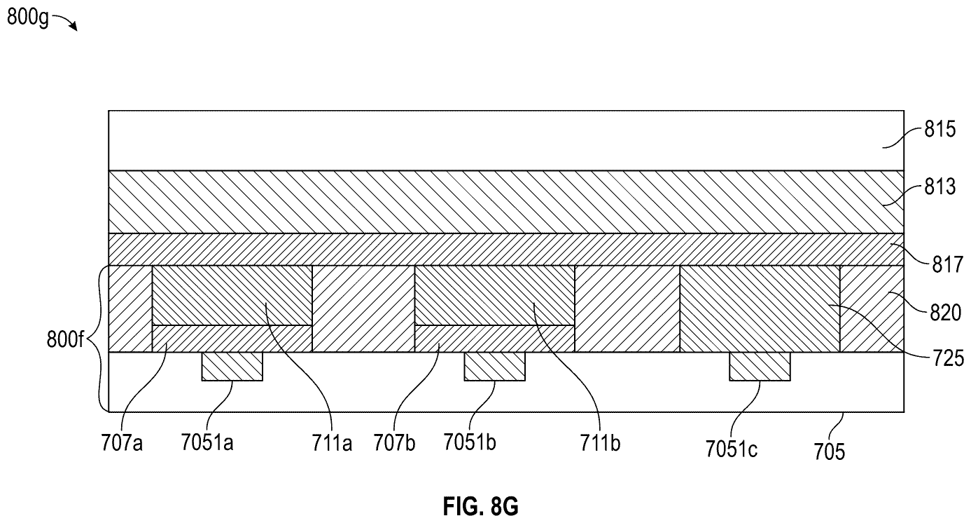

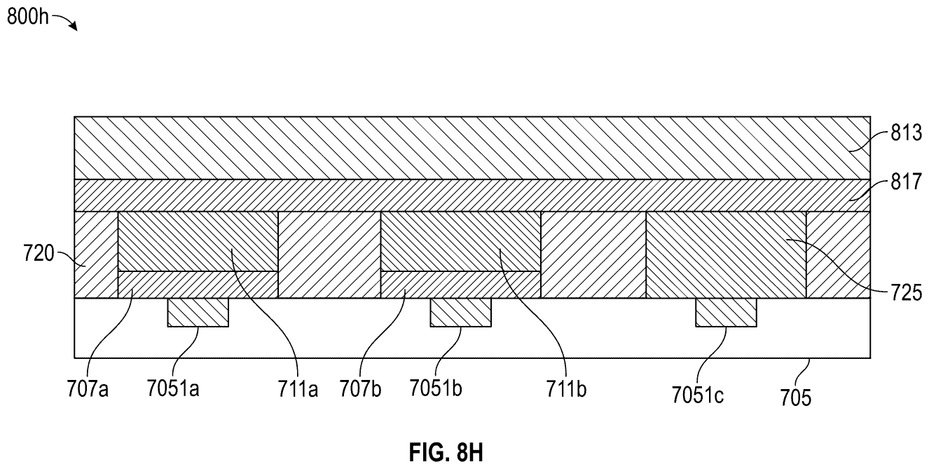

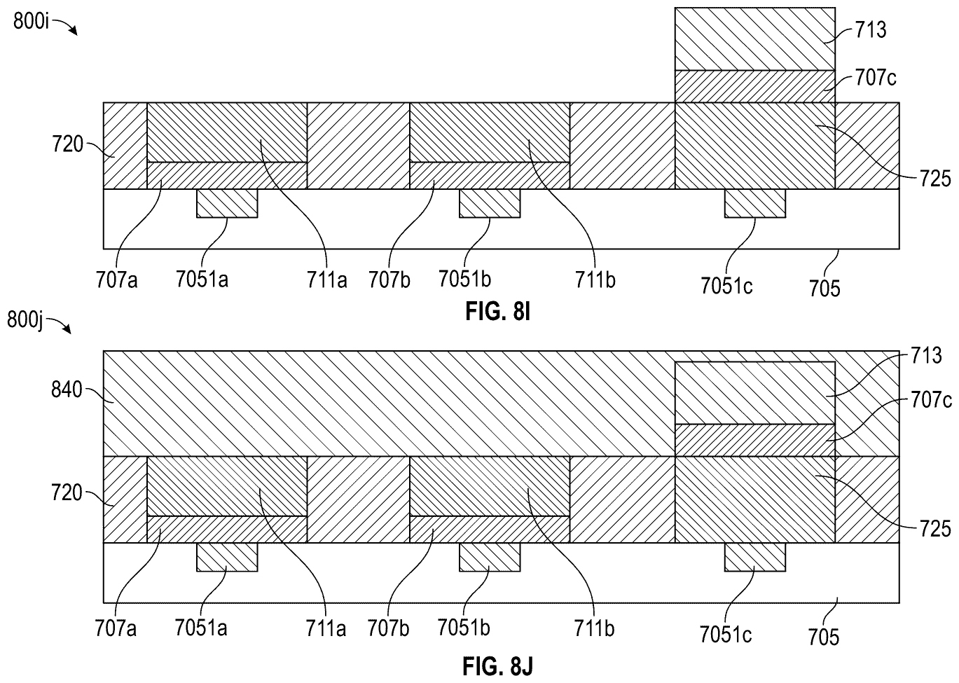

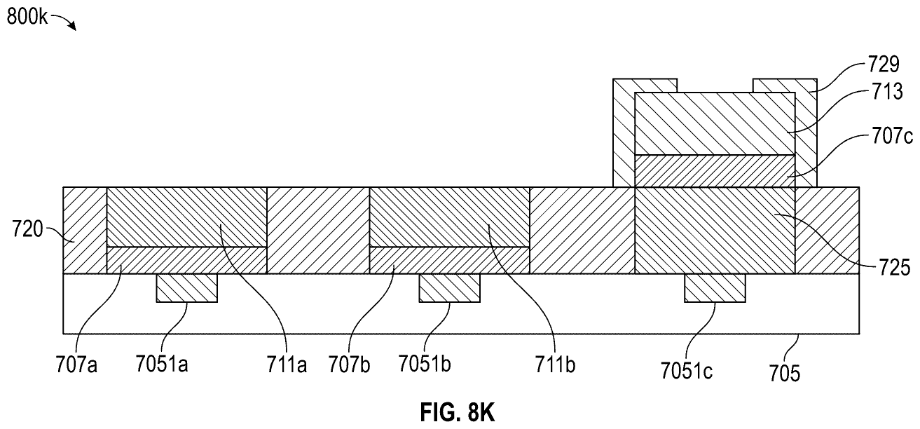

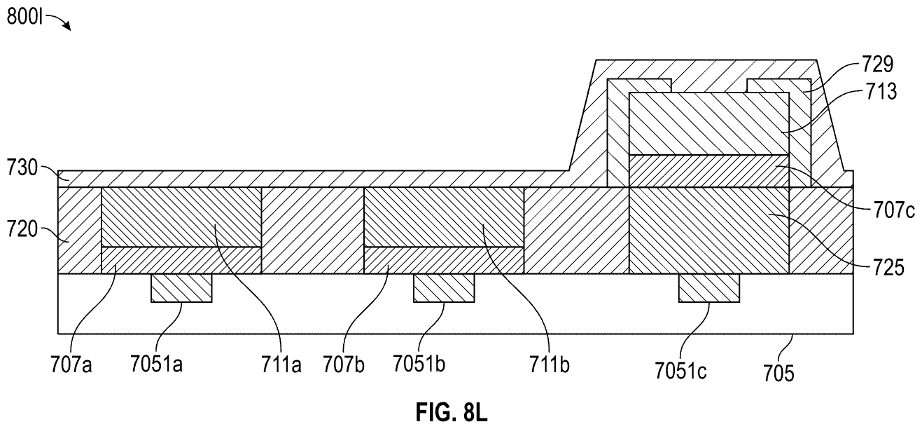

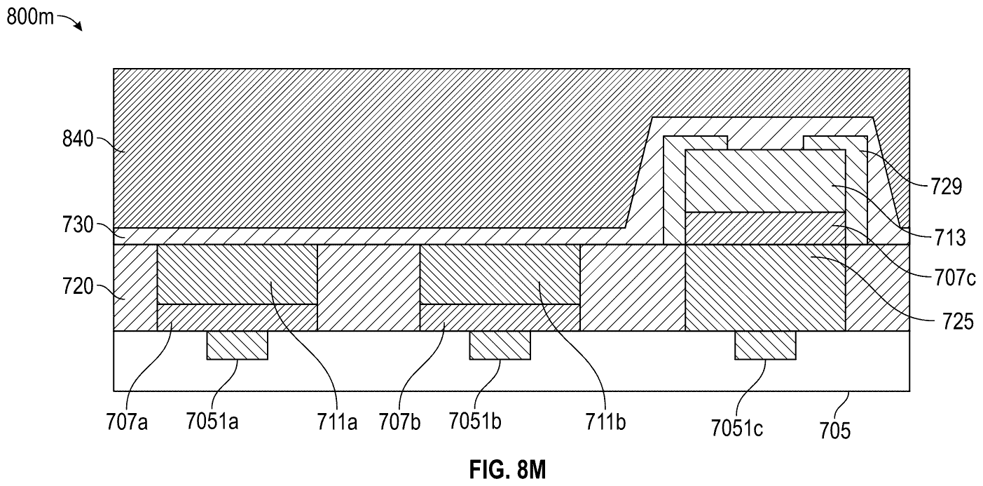

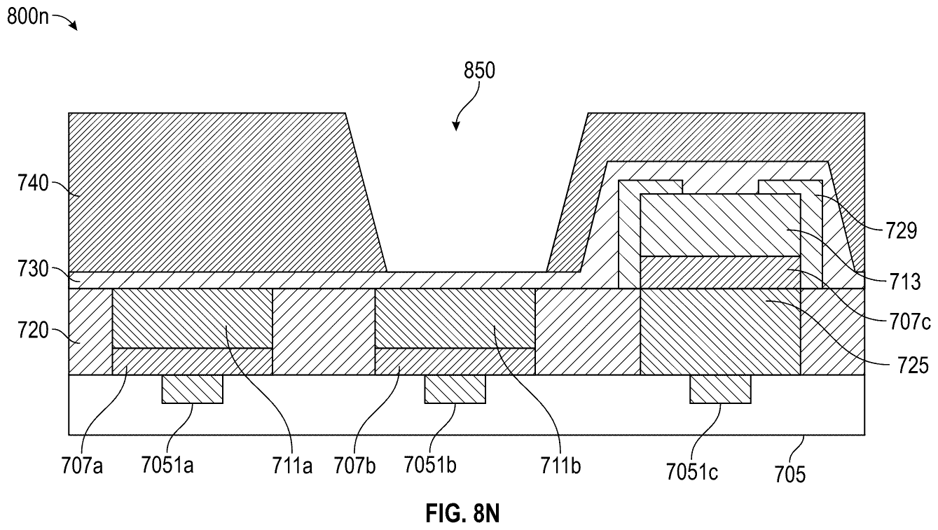

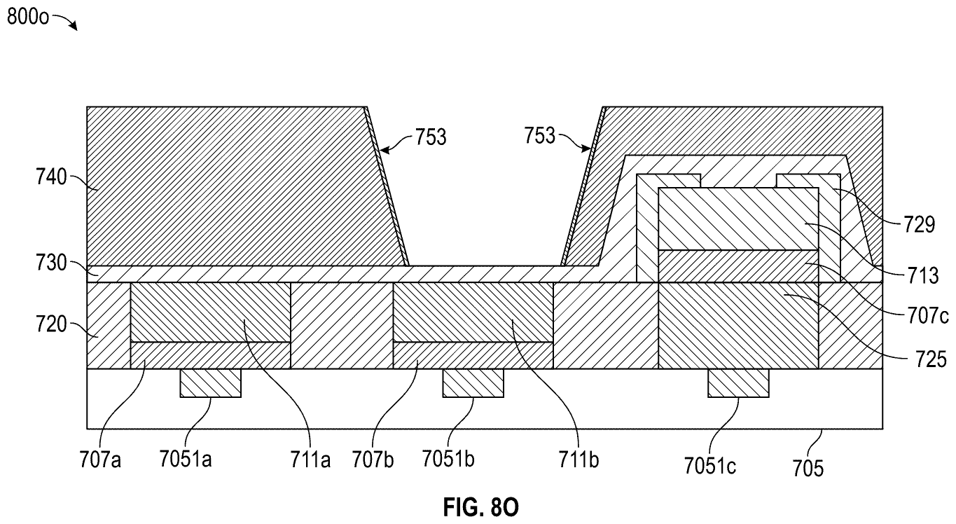

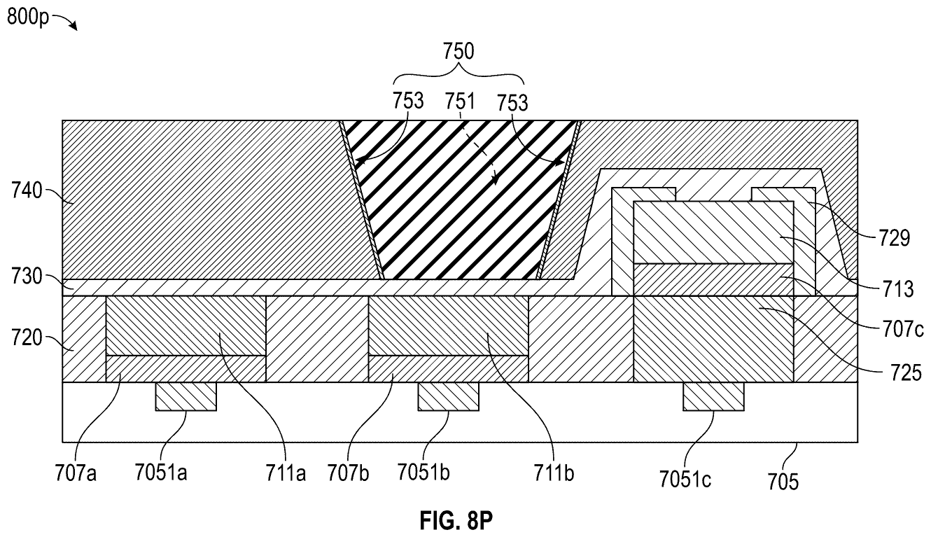

FIGS. 8A-8P are diagrams showing cross-sectional views of device stacks 800a, 800b, 800c, 800d, 800c, 800f, 800g, 800h, 800i, 800j, 800k, 800l, 800m, 800n, 800o, and 800p for fabricating apparatus 700 of FIG. 7 in accordance with some embodiments of the present disclosure.

Referring to FIG. 8A, a light-emitting stack 811 may be bonded to substrate 705 via a bonding layer 807 (e.g., utilizing a metal bonding or any other suitable bonding process). Bonding layer 807 may include any suitable conductive material that may bond light-emitting stack 811 to substrate 705, such as an Au—Sn alloy, indium, etc. Light-emitting stack 811 may contain one or more epitaxial layers of a group III-V material, such as an n-GaN layer, an active layer for emitting light of the first color, a p-GaN layer, etc. As an example, light-emitting stack 811 may be and/or include light-emitting structure 205 of FIG. 2. As another example, light-emitting stack 811 may be and/or include the light-emitting stack 320 as described in connection with FIG. 3B. As a further example, light-emitting stack 811 may be and/or include the semiconductor device 310 of FIGS. 3A and/or 3B. In some embodiments, a p-GaN layer of light-emitting stack 811 may be bonded to substrate 705 via bonding layer 807.

Light-emitting stack 811 may be patterned and etched to fabricate a plurality of light-emitting devices for emitting light of the first color (e.g., blue light). For example, as shown in FIG. 8B, light-emitting devices 711a, 711b, and 711c may be fabricated by patterning and etching light-emitting stack 811. The patterning and etching of bonding layer 807 may fabricate conductive bonding layers 707a, 707b, and 707d.

As shown in FIG. 8C, the light-emitting device 711c and the conductive bonding layer 707d may be removed. Conductive pad 7051c may be exposed by the removal of the light-emitting device 711c and the conductive bonding layer 707d.

As shown in FIG. 8D, a dielectric layer 820 may be fabricated on substrate 705. Dielectric layer 820 may cover the sidewalls of light-emitting devices 711a and 711b and at least a portion of the top surface of substrate 705. Dielectric layer 820 may cover conductive pad 7051c.

As shown in FIG. 8E, dielectric layer 820 may be patterned and etched to expose conductive pad 7051c. The etching of dielectric layer 820 may fabricate a via 825.

As shown in FIG. 8F, conductive via 725 may be fabricated in via 825 by filling via 825 with one or more suitable conductive materials, such as metals (e.g., Cu, Au, Al, etc.), alloys, conductive nitrides (e.g., titanium nitride (TiN), tantalum nitride (TaN), tungsten nitride (WNₓ), etc.). Conductive via 725 may directly contact conductive pad 7051c in some embodiments.

As shown in FIG. 8G, a light-emitting stack 813 may be bonded to device stack 800f through a conductive bonding layer 817. Light-emitting stack 813 may be fabricated on a growth template 815. Conductive bonding layer 817 may include any suitable conductive material that may bond light-emitting stack 813 to device stack 800f, such as an Au—Sn alloy, indium, etc. Light-emitting stack 813 may contain one or more epitaxial layers of a group III-V material (e.g., GaN), such as an n-GaN layer, an active layer for emitting light of the second color, a p-GaN layer, etc. As an example, light-emitting stack 813 may be and/or include light-emitting structure 205 of FIG. 2. In some embodiments, light-emitting stack 813 may be and/or include a light-emitting stack 340 as described in connection with FIG. 3H above. In some embodiments, a p-GaN layer of light-emitting stack 813 may be bonded to device stack 800f (the top surface of first dielectric layer 720, light-emitting devices 711a, light-emitting devices 711b, and conductive via 725) through conductive bonding layer 817.

As shown in FIG. 8H, growth template 815 may be removed. In some embodiments, light-emitting stack 813 may be thinned.

As shown in FIG. 8I, light-emitting stack 813 and conductive bonding layer 817 may be patterned and etched to fabricate light-emitting device 713 and conductive bonding layer 707c. As such, light-emitting device 713 is bonded to conductive via 725 via conductive bonding layer 707c and electrically connected to conductive pad 7051c via conductive bonding layer 707c and conductive via 725.

As shown in FIG. 8J, a dielectric layer 840 may be fabricated on first dielectric layer 720, light-emitting devices 711a, light-emitting devices 711b, and light-emitting device 713. Dielectric layer 840 may also cover the sidewalls of conductive bonding layer 707c.

As shown in FIG. 8K, dielectric layer 840 may be patterned and etched to expose at least a portion of the top surface of light-emitting device 713. The etched dielectric layer 840 may be the dielectric material 729 of FIG. 7.

As shown in FIG. 8L, electrode layer 730 may be fabricated on first dielectric layer 720, light-emitting devices 711a, light-emitting devices 711b, light-emitting device 713, and the dielectric material 729. Electrode layer 730 may include any suitable conductive material. In some embodiments, electrode layer 730 may include ITO and other suitable materials to implement a transparent conductive electrode for light-emitting devices 711a, 711b, and 713. In some embodiments, electrode layer 730 may be a continuous and/or substantially continuous layer of the conductive material. Electrode layer 730 may provide ohmic contact for light-emitting devices 711a, 711b, and 713. In some embodiments, electrode layer 730 may directly contact at least a portion of the top surface of each of light-emitting devices 711a, 711b, and 713.

As shown in FIG. 8M, a dielectric layer 840 may be fabricated on electrode layer 730. Dielectric layer 840 may include one or more dielectric materials, such as SiO₂, Si₃N₄, etc.

As shown in FIG. 8N, one or more portions of dielectric layer 840 may be selectively removed to fabricate a via 850. For example, dielectric layer 840 may be patterned and etched to expose a portion of electrode layer 730 that covers light-emitting device 711b. The etched dielectric layer 840 may be referred to as the second dielectric layer 740.

As shown in FIG. 8O, the sidewalls of via 850 may be coated with one or more reflective materials 753. The reflective materials 753 may be, for example, one or more metallic materials.

As shown in FIG. 8P, quantum dots 751 may be placed in via 850 to fabricate light-conversion structure 750. In some embodiments, quantum dots 751 may fill via 850 so that the top surfaces of light-conversion structure 750 and dielectric layer 740 may conform or substantially conform. The conforming surface may facilitate the subsequent fabrication of micro-lenses on the light-conversion structure 750 and the second dielectric layer 740.

A plurality of micro-lenses may be fabricated on the second dielectric layer 740 to fabricate apparatus 700 as described in connection with FIG. 7.

FIG. 9 is a diagram illustrating a cross-sectional view of an example apparatus 900 incorporating micro light-emitting devices in accordance with some embodiments of the present disclosure.

As shown, apparatus 900 may include light-emitting devices 911a, . . . , 911b for emitting light of a first color (e.g., blue light). The light-emitting device for emitting light of the first color may be bonded to a substrate 905 via a first dielectric bonding layer 907 and a conductive bonding layer 907a-907c. Bonding pads 907a-907c may be fabricated in first dielectric bonding layer 907 in some embodiments. First dielectric bonding layer 907 may include one or more insulating materials, such as silicon oxide (SiO₂), silicon nitride (Si₃N₄), or any other suitable dielectric materials used in oxide bonding processes. Each bonding pad may include conductive materials, such as a metallic material (e.g., copper (Cu), gold (Au), aluminum (Al), etc., or alloys thereof). Light-emitting device 911a may be bonded to substrate 105 through a first dielectric bonding layer 907 and conductive bonding layer 907a. Light-emitting device 911b may be bonded to substrate 105 through first dielectric bonding layer 907 and conductive bonding layer 907b.

Substrate 905 may be substrate 105 of FIG. 1A. Substrate 905 may include conductive pad 9051a, 9051b, and 9051c, each of which may include any suitable conductive material. In some embodiments, substrate 105 may be a CMOS substrate and each of conductive pads 9051a-c may be an interconnect of the CMOS substrate. Light-emitting devices 911a and 911b may be bonded to conductive pads 9051a and 9051b, respectively.

Each light-emitting device 711a-711b may include a light-emitting structure 205 as described in connection with FIG. 2 above. The light-emitting devices 911a-911b for emitting the first color and the conductive via 925 may be separated by a first dielectric layer 920. A conductive via 925 may be fabricated in first dielectric layer 920. Conductive via 925 may include any suitable conductive material, such as metals (e.g., Cu, Au, Al, etc.), alloys, conductive nitrides (e.g., titanium nitride (TiN), tantalum nitride (TaN), tungsten nitride (WNₓ), etc.).

Apparatus 900 may further include a light-emitting device 913 for emitting light of the second color (e.g., green light). Each of light-emitting devices 911a, 911b, and 913 may be a micro-LED in some embodiments. Light-emitting device 913 may be bonded to conductive via 925 via a second dielectric bonding layer 909 and a conductive bonding layer 9091 fabricated in second dielectric bonding layer 909. Second dielectric bonding layer 909 may include an insulating material such as SiO₂, Si₃N₄, or any other suitable dielectric materials used in oxide bonding processes. Conductive bonding layer 9091 may include one or more conductive materials, such as a metallic material (e.g., Cu, Au, Al, etc., or alloys thereof). Conductive via 925 is bonded to conductive pad 9051c through first dielectric bonding layer 907 and conductive bonding layer 907c. As such, the light-emitting device 913 is electrically connected to the conductive pad 9051c through conductive bonding layer 9091, conductive via 925, and conductive bonding layer 907c.

The sidewalls and one or more portions of the top surface of the light-emitting device 913 may be covered by dielectric materials 929. At least a portion of the top surface of light-emitting device 913 is not covered by dielectric materials 929. Electrode layer 930 may provide ohmic contact for light-emitting devices 911a, 911b, and 913 and may contain transparent conductive materials, such as ITO. In some embodiments, electrode layer 930 may directly contact the top surfaces of light-emitting devices 911a, 911b, and/or 913.

A second dielectric layer 940 may be fabricated on electrode layer 930. Second dielectric layer 940 may include any suitable dielectric material, such as SiO₂, Si₃N₄, etc.

Apparatus 900 may further include a light-conversion structure 950 that may convert light of the first color into light of the third color. Light-conversion structure 950 may include quantum dots 951 for converting light of the first color into light of the third color. In some embodiments, quantum dots 951 may convert blue light into red light. In some embodiments, light-conversion structure 950 may be a via fabricated in second dielectric layer 940 with sidewalls coated with one or more reflective materials 953 and filled with quantum dots 951.

Apparatus 900 may further include micro-lenses 960a, 960b, . . . , 960c fabricated on light-conversion structure 950 and second dielectric layer 940. Micro-lenses 960a, 960b, . . . , 960c may enhance the extraction and directionality of the light emitted by light-emitting devices 911a, 911b, . . . , 913. In particular, micro-lens 960a may be fabricated on a portion of second dielectric layer 940 that covers the first pixel and may enhance the extraction and directionality of the light produced by light-emitting device 911a (e.g., blue light). Micro-lens 960b may be fabricated on light-conversion structure 950 and may enhance the extraction and directionality of the light produced by light-conversion structure 950 (e.g., red light). Micro-lens 960c may be fabricated on a portion of second dielectric layer 940 that covers light-emitting device 913 and may enhance the extraction and directionality of the light produced by light-emitting device 913 (e.g., green light).

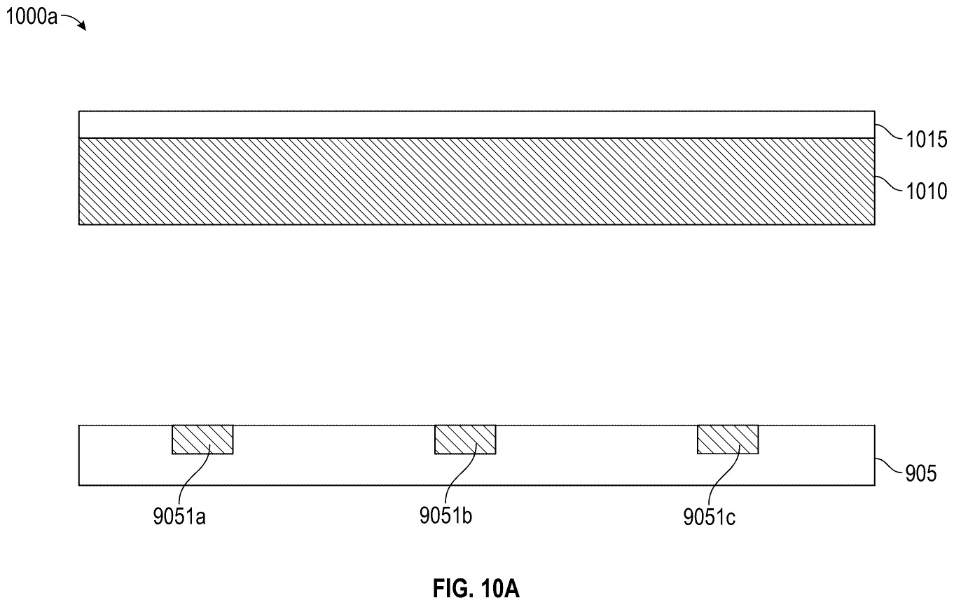

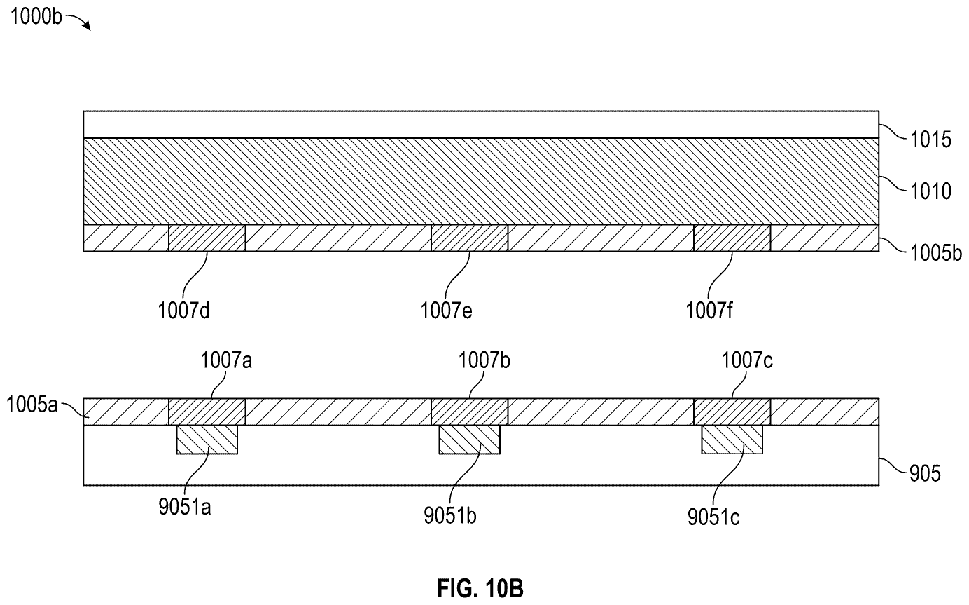

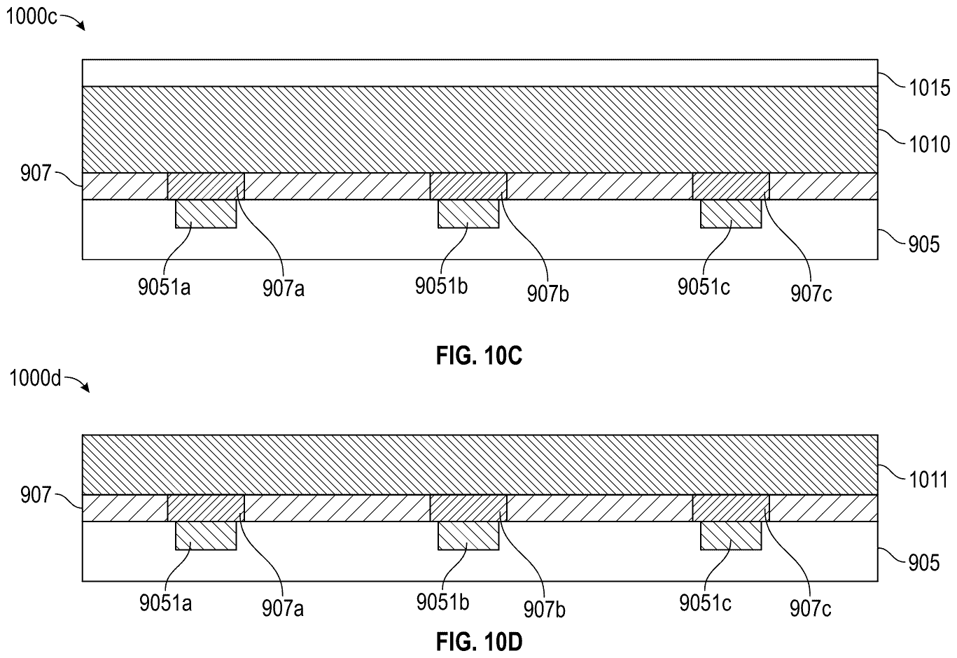

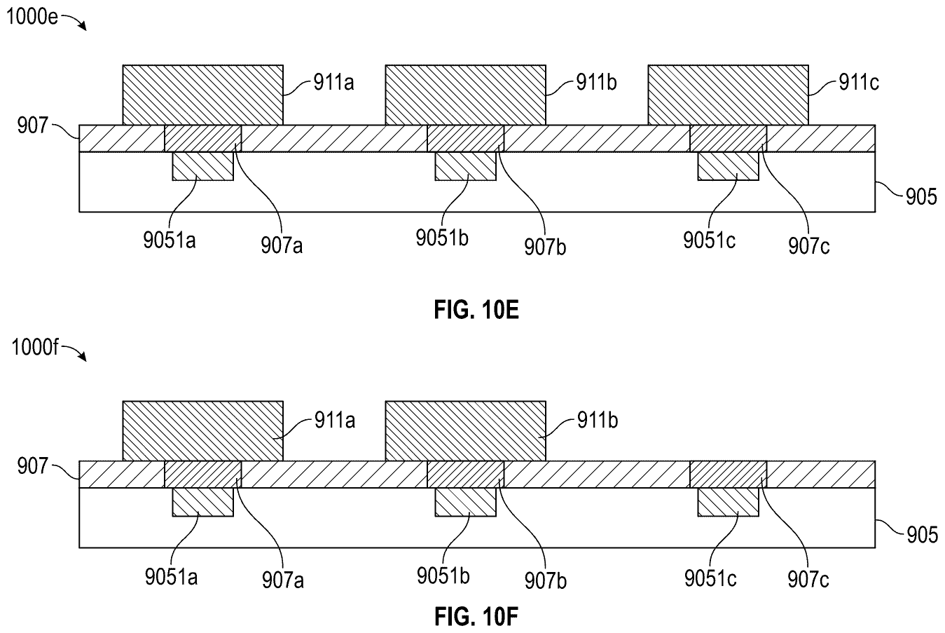

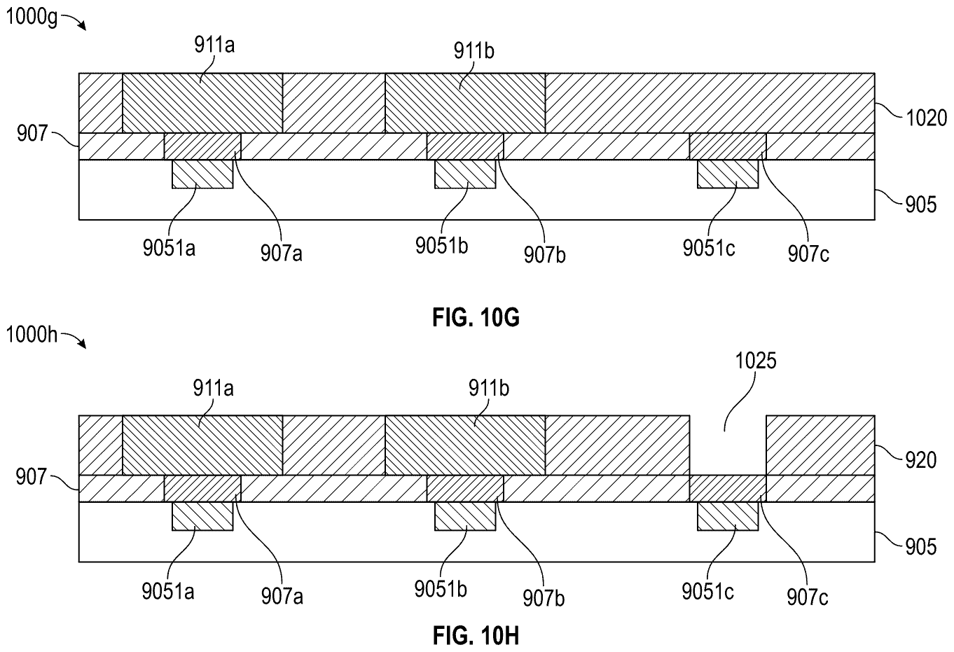

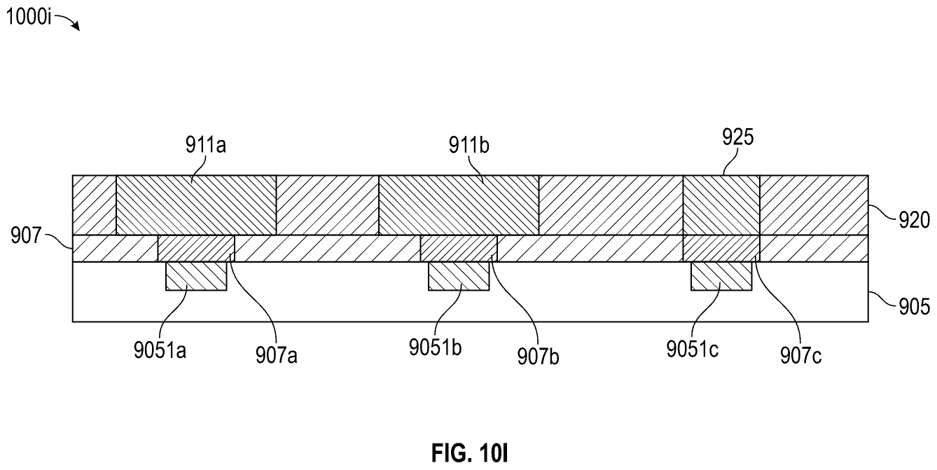

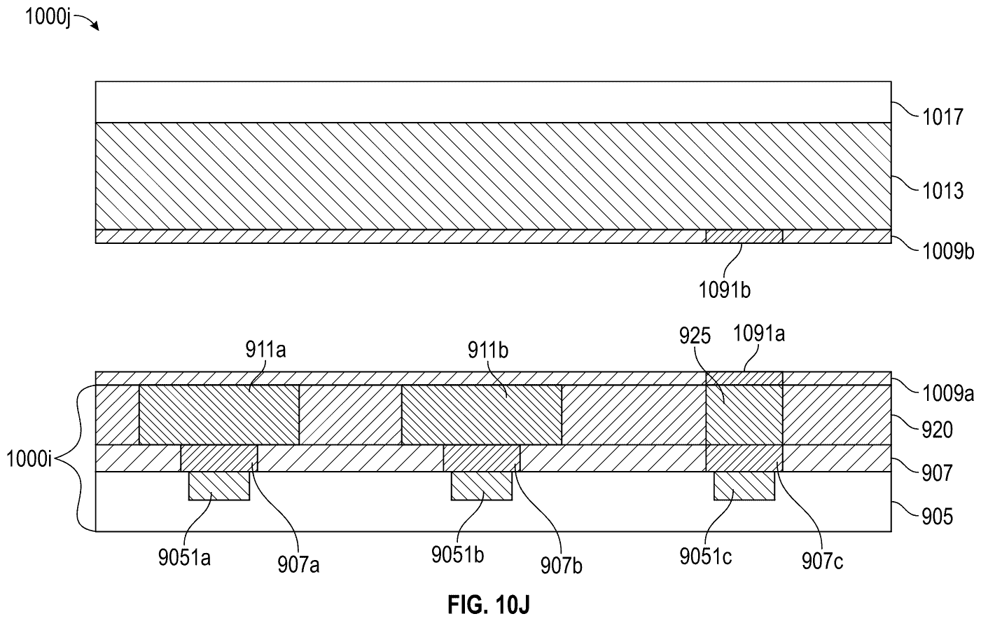

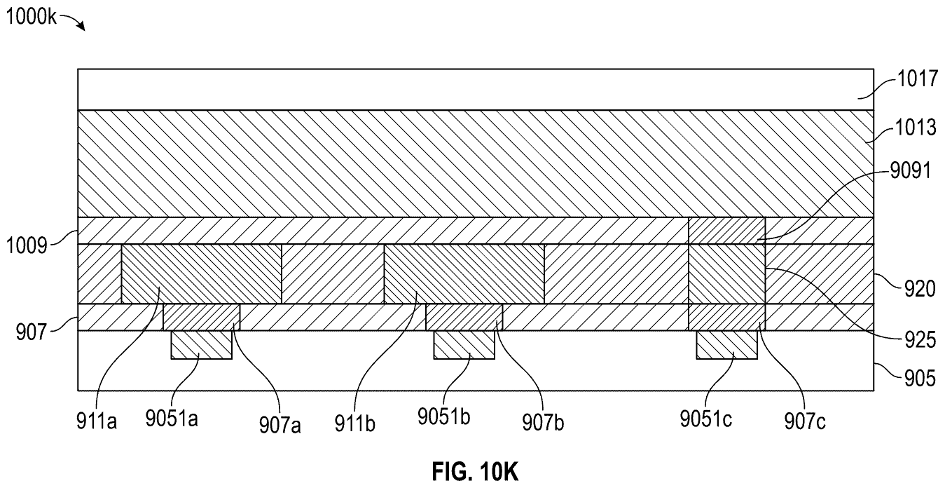

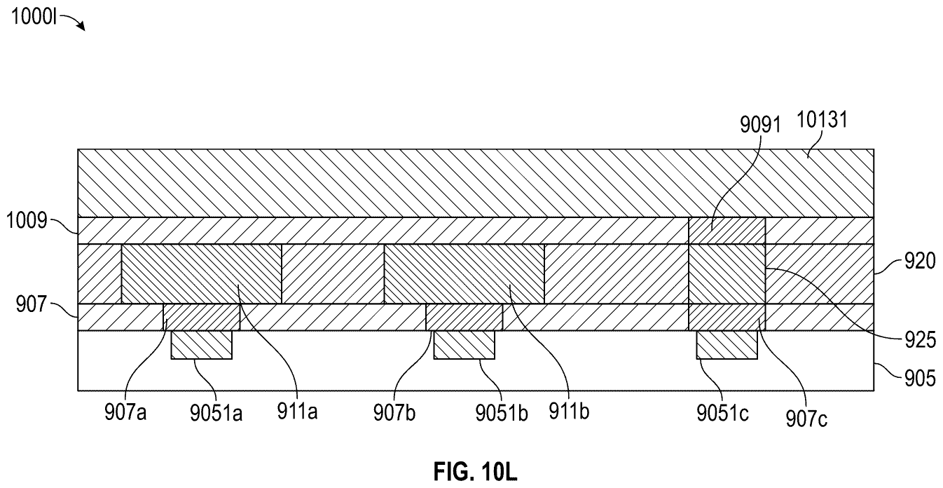

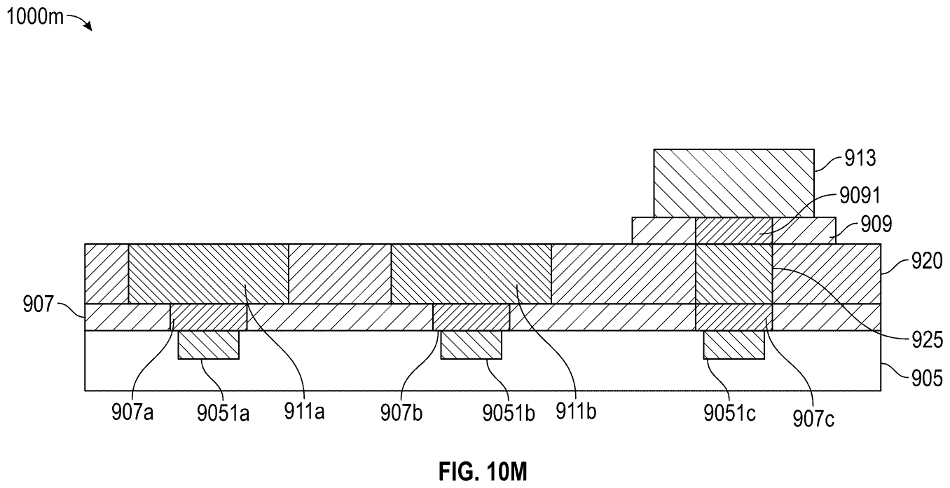

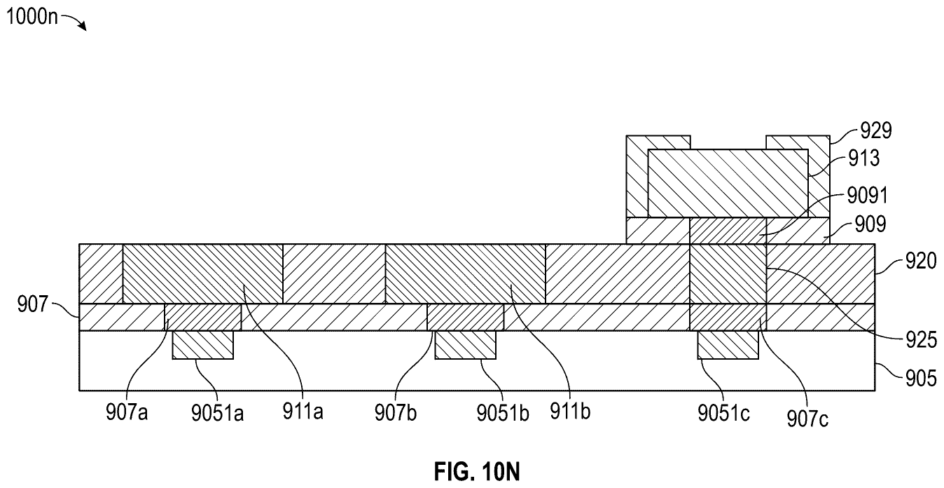

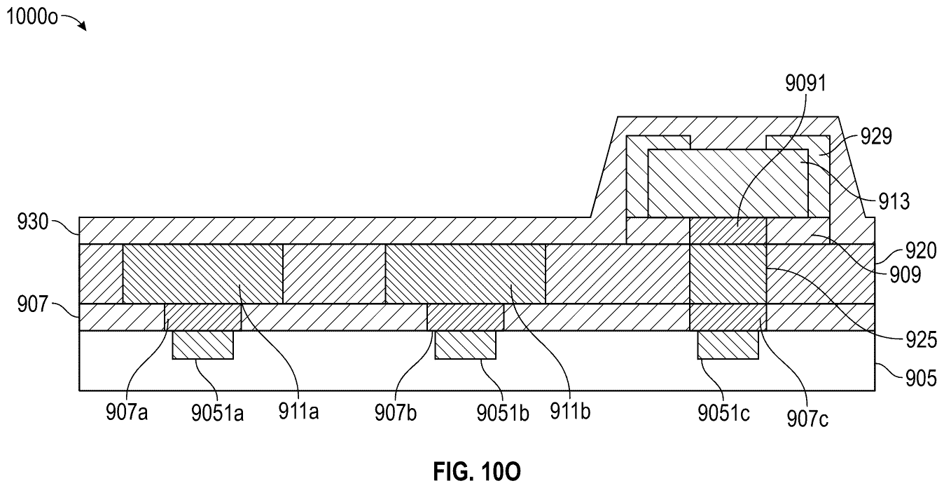

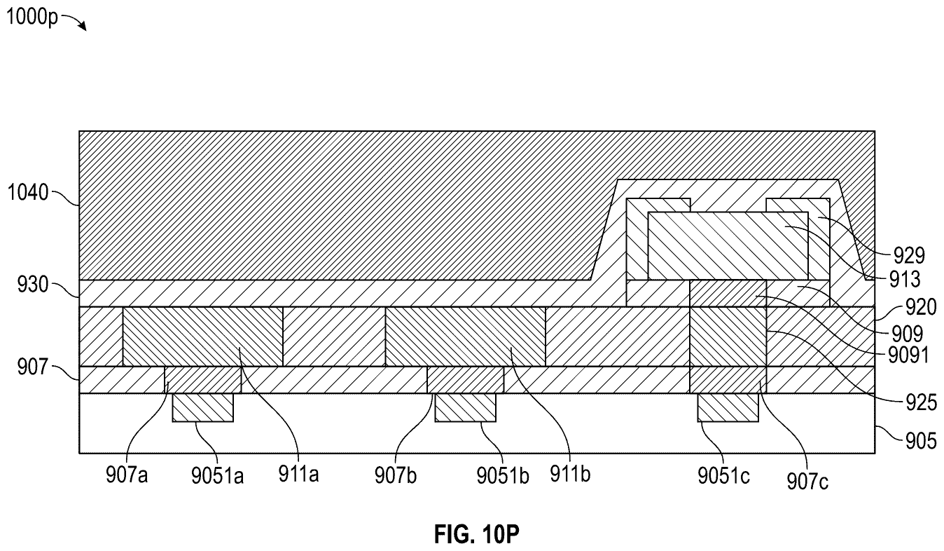

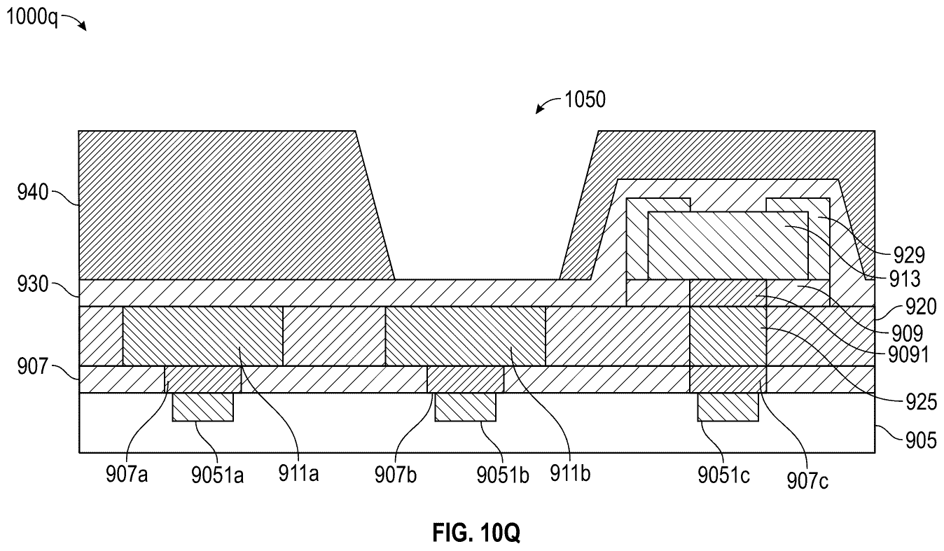

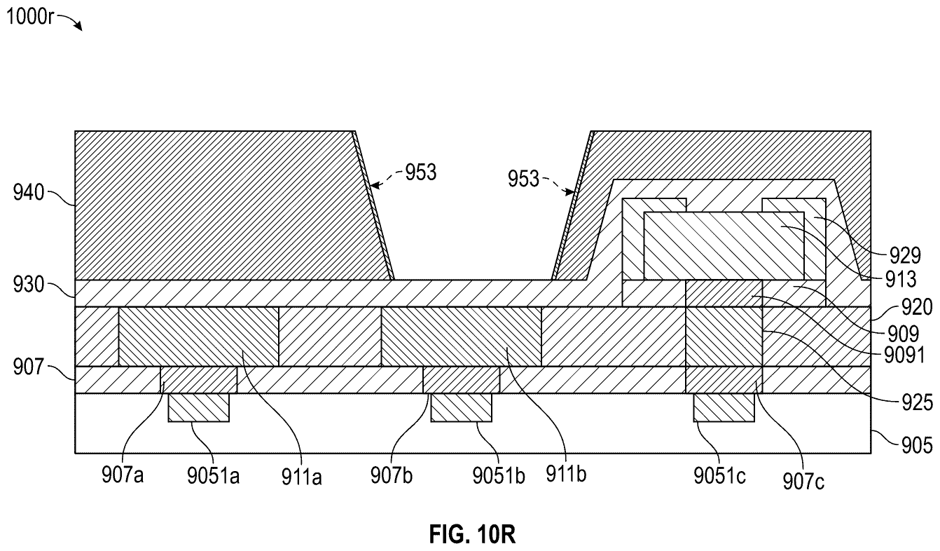

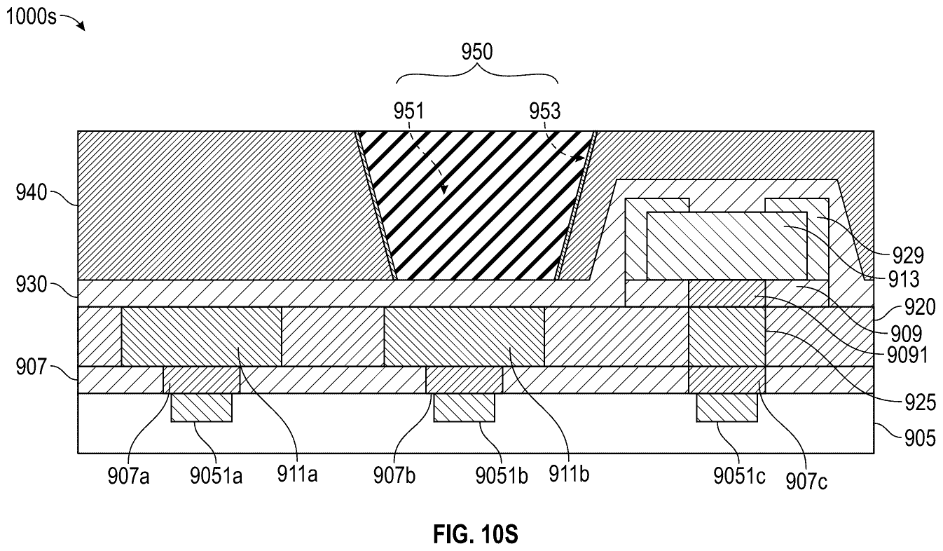

FIGS. 10A-10S are diagrams showing cross-sectional views of device stacks 1000a, 1000b, 1000c, 1000d, 1000c, 1000f, 1000g, 1000h, 1000i, 1000j, 1000k, 1000l, 1000m, 1000n, 1000o, 1000p, 1000q, 1000r, and 1000s for fabricating apparatus 900 of FIG. 9 in accordance with some embodiments of the present disclosure.

Referring to FIG. 10A, a light-emitting stack 1010 and substrate 905 may be provided. Light-emitting stack 1010 may contain one or more epitaxial layers of a group III-V material, such as one or more n-GaN layers, an active layer, a p-GaN layer, etc. The active layer may be configured to emit light of the first color. Light-emitting stack 1010 may be fabricated on a growth template 1015. Light-emitting stack 1010 may be and/or include light-emitting structure 205 of FIG. 2. In some embodiments, light-emitting stack 1010 may be and/or include the light-emitting stack 320 as described in connection with FIG. 3B. In some embodiments, light-emitting stack 1010 may be and/or include the semiconductor device 310 of FIGS. 3A and/or 3B.

Referring to FIG. 10B, a bonding layer 1005a and bonding pads 1007a, 1007b, and 1007c may be fabricated on substrate 905 for hybrid bonding substrate 905 to light-emitting stack 1010. Similarly, a bonding layer 1005b and bonding pads 1007d, 1007e, and 1007f may be fabricated on light-emitting stack 1010 for bonding light-emitting stack 1010 to substrate 905 utilizing a hybrid bonding process. Each bonding layer 1005a and 1005b may include one or more insulating materials, such as SiO₂, Si₃N₄, or any other suitable dielectric materials used in oxide bonding processes. Each bonding pad 1007a, 1007b, 1007c, 1007d, 1007c, and 1007f may include conductive materials, such as a metallic material (e.g., Cu, Au, Al, etc., or alloys thereof). The fabrication of the bonding layer 1005a and the bonding pads 1007a-1007c may involve depositing a layer of dielectric material (e.g., SiO₂ or Si₃N₄) on the top surface of substrate 905, followed by precise patterning through photolithography and etching to form a bonding pad region. In some embodiments, a planarization process (e.g., CMP (chemical-mechanical planarization) may be performed on the bonding layer to remove surface irregularities that may hinder the hybrid bonding process and to ensure a flat and smooth surface for subsequent hybrid bonding. Conductive materials, such as Cu, Au, Al, etc. may then be deposited on the bonding pad region to form bonding pad 1007a-1007c. Bonding layer 1005b and bonding pad 1007d-1007f may be fabricated in a similar manner, with bonding pads 1007a, 1007b, and 1007c aligned with bonding pads 1007d, 1007e, and 1007f, respectively.

After the alignment of bonding layers 1007a-1007b with bonding pads 1009a-e, hybrid bonding may occur through a combination of oxide bonding for dielectric bonding layers 1007a-1007b and metallic bonding for bonding pads 1009a-1009c. For example, as shown in FIG. 10C, light-emitting stack 1010 may be bonded to substrate 905 via a first dielectric bonding layer 907 (the combination of bonding layers 1007a-1007b), conductive bonding layer 907a (the combination of bonding pads 1007a and 1007d), conductive bonding layer 907b (the combination of bonding pads 1007b and 1007c), and conductive bonding layer 907c (the combination of bonding pads 1007c and 1007f).

As shown in FIG. 10D, growth template 1015 may be removed. Light-emitting stack 1010 may be thinned to form a light-emitting stack 1011.

Light-emitting stack 1011 may be patterned and etched to fabricate a plurality of light-emitting devices for emitting light of the first color (e.g., blue light). For example, as shown in FIG. 10E, light-emitting devices 911a, 911b, and 911c may be fabricated by the patterning and etching of light-emitting stack 1011.

As shown in FIG. 10F, light-emitting device 911c may be removed. Conductive pad 9051c may be exposed by the removal of light-emitting device 911c.

As shown in FIG. 10G, a dielectric layer 1020 may be fabricated on substrate 905. Dielectric layer 1020 may cover the sidewalls of light-emitting devices 911a and 911b and at least a portion of the top surface of substrate 905. Dielectric layer 1020 may cover the conductive pad 7051c.

As shown in FIG. 10H, dielectric layer 1020 may be patterned and etched to expose conductive pad 9051c. The etching of dielectric layer 1020 may fabricate a via 1025 and dielectric layer 920.

As shown in FIG. 10I, conductive via 925 may be fabricated in via 1025 by filling via 1025 with one or more suitable conductive materials. Conductive via 925 may directly contact conductive pad 9051c in some embodiments.

As shown in FIG. 10J, a light-emitting stack 1013 may be provided. Light-emitting stack 1013 may be fabricated on a growth template 1017. Light-emitting stack 1013 may contain one or more epitaxial layers of a group III-V material, such as an n-GaN layer, an active layer for emitting light of the second color, a p-GaN layer, etc. As an example, light-emitting stack 1013 may be and/or include light-emitting structure 205 of FIG. 2. In some embodiments, light-emitting stack 1013 may be and/or include a light-emitting stack 340 as described in connection with FIG. 3H above.

A bonding layer 1009a may be fabricated on light-emitting devices 911a-911b, conductive via 925, and dielectric layer 920. A bonding layer 1091a may be fabricated on conductive via 925 for hybrid bonding to light-emitting stack 1013. Bonding layer 1091a may be fabricated in bonding layer 1009a. A bonding layer 1009b and a bonding layer 1091b are fabricated on light-emitting stack 1013 for hybrid bonding to device stack 1000i. Each bonding layer 1009a and 1009b may include one or more insulating materials, such as SiO₂, Si₃N₄, or any other suitable dielectric materials used in oxide bonding processes. Each bonding layer 1091a and 1091b may include conductive bonding materials, such as a metallic material (e.g., Cu, Au, Al, etc., or alloys thereof). The fabrication of the bonding layer 1009a and the bonding layer 1091a may involve depositing a layer of dielectric material (e.g., SiO₂ or Si₃N₄) on the top surface of device stack 1000i, followed by precise patterning through photolithography and etching to form a bonding pad region. In some embodiments, a planarization process (e.g., CMP (chemical-mechanical planarization) may be performed on the bonding layer to remove surface irregularities that may hinder the hybrid bonding process and to ensure a flat and smooth surface for subsequent hybrid bonding. Conductive materials, such as Cu, Au, Al, etc., may then be deposited on the bonding pad region to form bonding layer 1091a. Bonding layer 1091a and bonding layer 1091b may be fabricated in a similar manner, with bonding layer 1091a aligned with bonding layer 1091b.

After the alignment of bonding layers 1090a-1090b with bonding layers 1091a-1091b, hybrid bonding may occur through a combination of oxide bonding for dielectric bonding layers 1009a-1009b and metallic bonding for bonding layers 1091a-1091b. As shown in FIG. 10K, light-emitting stack 1013 may be bonded to substrate 905 via bonding layer 1009 (the combination of bonding layers 1009a and 1009b) and conductive bonding layer 9091 (the combination of bonding layers 1091a and 1091b).

As shown in FIG. 10L, growth template 1017 may be removed. Light-emitting stack 1013 may be thinned to form light-emitting stack 10131.

As shown in FIG. 10M, light-emitting stack 10131 may be patterned and etched to fabricate light-emitting device 913. Bonding layer 1009 may be patterned and etched to fabricate second dielectric bonding layer 909.

As shown in FIG. 10N, the sidewalls and a portion of the top surface of light-emitting device 913 may be covered by dielectric materials 929. In some embodiments, dielectric materials 929 may be fabricated on light-emitting device 913 by fabricating a layer of the dielectric materials (not shown) on dielectric layer 920 and light-emitting device 913 and patterning and etching the layer of the dielectric materials to expose a portion of the top surface of light-emitting device 913.

As shown in FIG. 10O, electrode layer 930 may be fabricated on first dielectric layer 920, light-emitting device 911a, light-emitting device 911b, light-emitting device 913, and dielectric materials 929. Electrode layer 930 may include any suitable conductive material. In some embodiments, electrode layer 930 may include ITO and other suitable materials to implement a transparent conductive electrode for light-emitting devices 911a, 911b, and 913. In some embodiments, electrode layer 930 may be a continuous and/or substantially continuous layer of the conductive material. Electrode layer 930 may directly contact at least a portion of the top surface of each of light-emitting devices 911a, 911b, and 913 to provide ohmic contact for light-emitting devices 911a, 911b, and 913.

As shown in FIG. 10P, a dielectric layer 1040 may be fabricated on electrode layer 930 (e.g., by depositing a suitable dielectric material on the top surface of electrode layer 930).

As shown in FIG. 10Q, one or more portions of dielectric layer 1040 may be selectively removed to fabricate a via 1050. For example, dielectric layer 1040 may be patterned and etched to expose a portion of electrode layer 930 that covers light-emitting device 911b. The etched dielectric layer 1040 may be referred to as the second dielectric layer 940.

As shown in FIG. 10R, the sidewalls of via 1050 may be coated with one or more reflective materials 953. The reflective materials 953 may be, for example, one or more metallic materials.

As shown in FIG. 10S, quantum dots 951 may be placed in via 1050 to fabricate light-conversion structure 950. In some embodiments, quantum dots 951 may fill the via 1050 so that the top surfaces of light-conversion structure 950 and dielectric layer 940 may conform or substantially conform. The conforming surface may facilitate the subsequent fabrication of micro-lenses on the light-conversion structure 950 and the second dielectric layer 940.

A plurality of micro-lenses may be fabricated on the second dielectric layer 940 to fabricate apparatus 900 as described in connection with FIG. 9.

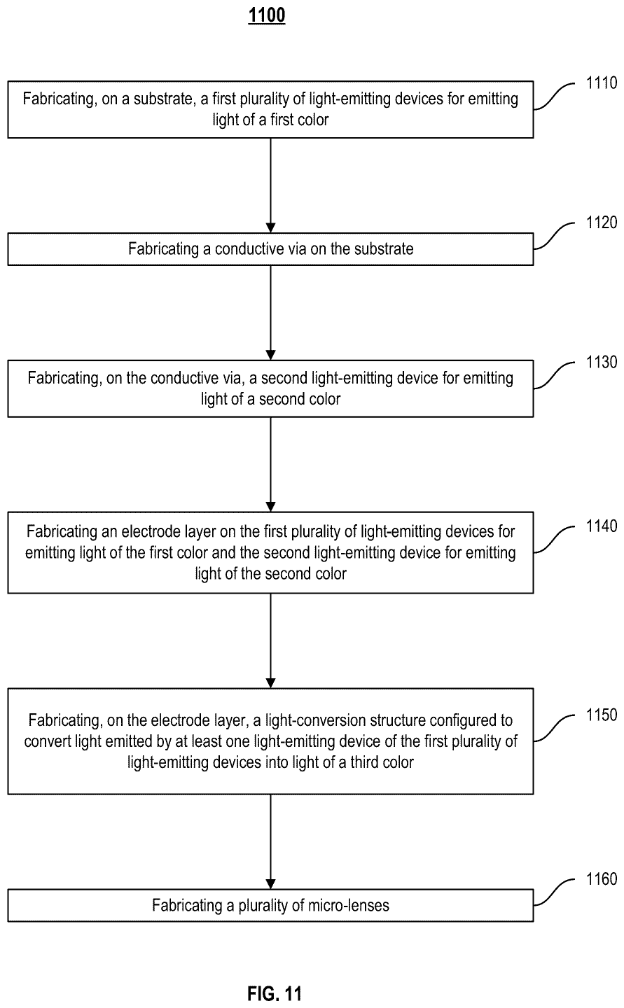

FIG. 11 is a flowchart of an example method 1100 for fabricating an apparatus containing light-emitting devices in accordance with some embodiments of the present disclosure.

At 1110, a first plurality of light-emitting devices for emitting light of a first color is fabricated on a substrate. For example, a first light-emitting stack may be bonded to the substrate. The first light-emitting stack may contain one or more epitaxial layers of a group III-V material, such as an n-GaN layer, an active layer for emitting light of the first color, a p-GaN layer, etc. The first light-emitting stack may be, for example, the light-emitting stack 811 of FIG. 8A or the light-emitting stack 1010 of FIG. 10A.

In one implementation, the first light-emitting stack may be bonded to the substrate using a metal bonding method through a conductive bonding layer (e.g., bonding layer 807 of FIG. 8A) containing one or more conductive bonding materials. The conductive bonding layer may be fabricated on the substrate and/or the light-emitting stack using metal deposition technologies such as sputtering, evaporation, electroplating, or chemical vapor deposition. In another implementation, the first light-emitting stack may be bonded to the substrate using a hybrid bonding method through a first dielectric bonding layer (e.g., first dielectric bonding layer 907 of FIG. 10C) containing an insulating material and a first plurality of conductive bonding layers containing conductive bonding materials (e.g., conductive bonding layers 907a, 907b, and 907c of FIG. 10C). The first dielectric bonding layer may be fabricated using dielectric deposition technologies such as chemical vapor deposition (CVD), spin coating, plasma-enhanced chemical vapor deposition (PECVD), etc. The bonding pads may be fabricated using photolithography, metal deposition, etching processes, etc.

The first light-emitting stack may be patterned and etched to fabricate the first plurality of light-emitting devices. As an example, the first plurality of light-emitting devices may include light-emitting devices 711a and 711b as described in connection with FIG. 8B and may be fabricated by performing operations as described in connection with FIGS. 8A-8B. As another example, the first plurality of light-emitting devices may include light-emitting devices 911a and 911b as described in connection with FIG. 10E and may be fabricated by performing operations as described in connection with FIGS. 10A-10E.

At 1120, a conductive via may be fabricated on the substrate. For example, a first dielectric layer may be fabricated on the substrate by depositing a first dielectric material (e.g., SiO₂, Si₃N₄, etc.) on the substrate. The first dielectric material may be deposited, for example, using deposition technologies such as CVD, PECVD, physical vapor deposition (PVD), etc. The first dielectric layer may cover the sidewalls of the first plurality of light-emitting devices. A first via may be created in the first dielectric layer (e.g., by patterning and etching the first dielectric layer). The first via may be, for example, via 825 of FIG. 8E and/or via 1025 of FIG. 10H. The conductive via (e.g., conductive via 725 of FIG. 8F or conductive via 925 of FIG. 10I) may be fabricated by depositing one or more suitable conductive materials (e.g., metals, alloys, conductive nitrides, etc.) in the first via.

At 1130, a second light-emitting device for emitting light of a second color may be fabricated on the conductive via. For example, a second light-emitting stack may be bonded to the conductive via. The second light-emitting stack may be patterned and etched to fabricate the second light-emitting device.

The second light-emitting stack may contain one or more epitaxial layers of a group III-V material, such as an n-GaN layer, an active layer for emitting light of the second color, a p-GaN layer, etc. In one implementation, the second light-emitting stack may be bonded to the conductive via using a metal bonding method through a second conductive bonding layer containing one or more conductive bonding materials (e.g., conductive bonding layer 817 of FIG. 8G). In another implementation, the second light-emitting stack may be bonded to the conductive via using a hybrid bonding method through a second dielectric bonding layer containing an insulating material (e.g., dielectric bonding layer 1009 of FIG. 10K) and a second conductive bonding layer containing conductive bonding materials (e.g., conductive bonding layer 9091 of FIG. 10K).

As an example, the second light-emitting device may include light-emitting device 713 as described in connection with FIG. 8I and may be fabricated by performing operations as described in connection with FIGS. 8G-8I. As another example, the second light-emitting device may include light-emitting device 913 described in connection with FIG. 10M and may be fabricated by performing operations as described in connection with FIGS. 10J-10M.

At 1140, an electrode layer may be fabricated on the first plurality of light-emitting devices and the second light-emitting device. The sidewalls and a portion of the top surface of the second light-emitting device may be covered by dielectric materials. Fabricating the electrode layer may involve depositing a layer of ITO or any other suitable conductive material on the top surfaces of the first plurality of light-emitting devices and the portion of the top surface of the second light-emitting device that is not covered by the dielectric materials. The conductive material may be deposited, for example, using sputtering, electron-beam evaporation, CVD, or any other suitable thin-film deposition techniques. In one implementation, the electrode layer may be electrode layer 730 of FIG. 8L and may be fabricated as described in connection with FIGS. 8J-8L. In another implementation, the electrode layer may be electrode layer 930 and may be fabricated by performing operations as described in connection with FIGS. 10N-10O.

At 1150, a light-conversion structure may be fabricated on the electrode layer. For example, a second dielectric layer (e.g., dielectric layer 840 of FIG. 8M or dielectric layer 1040 of FIG. 10P) may be fabricated on the electrode layer. The second dielectric layer may be patterned and etched to create a second via (e.g., via 850 of FIG. 8N or via 1050 of FIG. 10Q). The sidewalls of the second via may be coated with one or more reflective materials (e.g., reflective materials 753 of FIG. 8O or reflective materials 953 of FIG. 10R). A plurality of quantum dots (e.g., quantum dots 751 of FIG. 8P or quantum dots 951 of FIG. 10S) may be placed in the second via. The quantum dots and the light-emitting conversion structure may be configured to convert light emitted by at least one light-emitting device of the first plurality of light-emitting devices into light of a third color.

At 1160, a plurality of micro-lenses may be fabricated. In some embodiments, the micro-lenses may be fabricated on the second dielectric layer and the light-conversion structure. Each of the micro-lenses may concentrate, direct, and/or collimate light emitted by a respective light-emitting device. The fabrication of the micro-lenses on the dielectric layer may involve applying a layer of photoresist to the surfaces of the dielectric layer and the light-conversion structure, defining the micro-lens pattern through photolithography, and an etching process to shape the micro-lenses. The micro-lenses may be precisely aligned with the underlying light-emitting devices to optimize light collection and emission direction.

The terms “approximately,” “about,” and “substantially” may be used to mean within ±20% of a target dimension in some embodiments, within ±10% of a target dimension in some embodiments, within ±5% of a target dimension in some embodiments, and yet within ±2% in some embodiments. The terms “approximately” and “about” may include the target dimension.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

1. An apparatus, comprising:
a first plurality of light-emitting devices for emitting light of a first color;
a second light-emitting device for emitting light of a second color; and
a light-conversion structure that converts light emitted by at least one of the first plurality of light-emitting devices into light of a third color, wherein the light-conversion structure comprises a plurality of quantum dots comprised in a nanoporous structure.

2. The apparatus of claim 1, further comprising an electrode layer fabricated on the first plurality of light-emitting devices and the second light-emitting device.

3. The apparatus of claim 2, wherein the electrode layer comprises a transparent electrode material.

4. The apparatus of claim 3, wherein the transparent electrode material comprises indium tin oxide.

5. The apparatus of claim 2, wherein the electrode layer provides ohmic contact for the first plurality of light-emitting devices and the second light-emitting device.

6. The apparatus of claim 2, wherein the electrode layer directly contacts a portion of a top surface of the second light-emitting device.

7. The apparatus of claim 6, wherein sidewalls of the second light-emitting device are covered by a dielectric material.

8. The apparatus of claim 6, wherein the electrode layer directly contacts at least a portion of a top surface of each of the first plurality of light-emitting devices.

9. The apparatus of claim 2, further comprising a dielectric layer fabricated on the electrode layer, wherein the light-conversion structure is fabricated in the dielectric layer.

10. (canceled)

11. The apparatus of claim 9, further comprising a plurality of micro-lenses fabricated on the dielectric layer and the light-conversion structure.

12. The apparatus of claim 1, further comprising a substrate, wherein the first plurality of light-emitting devices is bonded to a first plurality of conductive pads of the substrate, wherein the second light-emitting device is electrically connected to a second conductive pad of the substrate through a conductive via.

13. The apparatus of claim 12, wherein the first plurality of light-emitting devices is bonded to the substrate through a first plurality of conductive bonding layers.

14. The apparatus of claim 12, wherein the conductive via is fabricated on the second conductive pad of the substrate.

15. The apparatus of claim 14, wherein the conductive via is bonded to the second conductive pad of the substrate.

16. The apparatus of claim 13, wherein the first plurality of light-emitting devices is further bonded to the substrate through a first dielectric bonding layer.

17. The apparatus of claim 13, wherein the second light-emitting device is bonded to the conductive via through a second conductive bonding layer.

18. The apparatus of claim 17, wherein the second light-emitting device is further bonded to the conductive via through a second dielectric bonding layer.

19. The apparatus of claim 1, wherein the first color comprises blue light, wherein the second color comprises green light, and wherein the third color comprises red light.

20. The apparatus of claim 19, wherein each of the first plurality of light-emitting devices and the second light-emitting device is a micro light-emitting device.
